(19) United States
(12) Patent Application Publication
(10) Pub. No.: US 2024/0244983 A1
(43) Pub. Date: Jul. 18, 2024

(54) MAGNETORESISTIVE EFFECT ELEMENT, MAGNETIC MEMORY AND ARTIFICIAL INTELLIGENCE SYSTEM

(71) Applicant: TOHOKU UNIVERSITY, Sendai-shi, Miyagi (JP)

(72) Inventors: Yoshiaki Saito, Sendai-shi (JP); Shoji Ikeda, Sendai-shi (JP); Tetsuo Endoh, Sendai-shi (JP)

(73) Assignee: TOHOKU UNIVERSITY, Sendai-shi, Miyagi (JP)

(21) Appl. No.: 18/282,277

(22) PCT Filed: Mar. 16, 2022
(86) PCT No.: PCT/JP2022/012083

§ 371 Date: Mar. 25, 2024

(30) Foreign Application Priority Data
Mar. 17, 2021 (JP) 2021-044188

(51) Int. Cl. H10N 50/10; H10B 61/00; H10N 50/85

(52) U.S. Cl. CPC H10N 50/10; H10B 61/00; H10N 50/85

(57) ABSTRACT

Provided are a magnetoresistive element in which the magnetization direction in a recording layer can be efficiently reversed with low resistance and without reducing reversal efficiency by a write current flowing in a heavy-metal layer; a magnetic memory; and an artificial intelligence system. A magnetoresistive element 10 includes: a heavy-metal layer 11 formed by stacking an Ir layer(s) 12 and a Pt layer(s) 13; a recording layer 16 provided to be opposed to the heavy-metal layer 11, and formed to include a first ferromagnetic layer having a reversible magnetization; a reference layer 18 formed to include a second ferromagnetic layer in which the magnetization direction is fixed; and a barrier layer 17 sandwiched between the first ferromagnetic layer and the second ferromagnetic layer, and formed of an insulator. The magnetization direction in the first ferromagnetic layer is reversed by a write current supplied to the heavy-metal layer 11.

### TECHNICAL FIELD

The present invention relates to a magnetoresistive effect element, a magnetic memory, and an artificial intelligence system.

### BACKGROUND ART

Writing information is the key to realize a spintronics integrated circuit. There is a method for electrically reversing magnetization in spintronics, a spin injection magnetization reversal technique. Specifically, a magnetic tunnel junction (MTJ) including: a recording layer including the first ferromagnetic layer having reversible magnetization; a tunnel barrier layer formed of an insulator; and a reference layer including the second ferromagnetic layer in which a magnetization direction is fixed, is supplied with current, reversing magnetization of the first ferromagnetic layer. Recently, a spin-orbit torque (SOT) induced magnetization switching method has been attracting a lot of attention and is being used for electrically reversing magnetization; and the method is applied to a magnetic random access memory (MRAM) element.

A SOT-MRAM element is provided with an MTJ including a recording layer/a tunnel barrier layer/a reference layer formed on a heavy-metal layer. When the heavy-metal layer is supplied with current, the spin-orbit coupling induces a spin current. The spin polarized by the spin Hall effect (spin current) is injected into the recording layer to reverse the magnetization in the recording layer, thereby switching between parallel state and antiparallel state with respect to the magnetization direction in the reference layer; and thus, data is recorded (Patent Literatures 1 to 3).

What also proposed is an electronic neuron with SOT-MRAM elements, where the magnetization direction of the neuron is determined by the total synaptic current, and a resistive crossbar array is used to function as a synapse that generates a bipolar current, that is, the weighted sum of input signals (Patent Literature 4).

### CITATION LIST

### Patent Literature

Patent Literature 1: WO 2016/021468 A1
Patent Literature 2: WO 2016/159017 A1
Patent Literature 3: WO 2016/159962 A1
Patent Literature 4: US 2017/0330070 A1

### SUMMARY OF INVENTION

### Technical Problem

The improvement of writing efficiency can be expected by using heavy-metal elements, such as β-W, for a heavy-metal layer in a SOT-MRAM element, however, because they have a high resistivity; it consumes much power.

Therefore, it is an object of the present invention to provide a magnetoresistive effect element in which the magnetization direction in a recording layer can be efficiently reversed with low resistance and without reducing reversal efficiency by a write current flowing in a heavy-metal layer; a magnetic memory and an artificial intelligence system.

### Solution to Problem

The present invention has the following concepts.

[1] A magnetoresistive effect element, including:
a heavy-metal layer formed by stacking an Ir layer and a Pt layer;
a recording layer provided to be opposed to the heavy-metal layer and formed to include a first ferromagnetic layer having a reversible magnetization;
a reference layer formed to include a second ferromagnetic layer in which a magnetization direction is fixed; and
a tunnel barrier layer sandwiched between the first ferromagnetic layer and the second ferromagnetic layer, and formed of an insulating materials;
wherein a magnetization direction in the first ferromagnetic layer is reversed by a write current flowing in the heavy-metal layer.
   [2] The magnetoresistive effect element according to [1],
wherein the heavy-metal layer is formed by repeatedly stacking the Ir layer and the Pt layer.
   [3] The magnetoresistive effect element according to [1] or [2],
wherein the Pt layer provided outermost on the heavy-metal layer forms an interface with the recording layer.
   [4] The magnetoresistive effect element according to any one of [1] to [3],
wherein the Pt layer of the heavy-metal layer has a thickness greater than 0.6 nm and equal to or less than 1.5 nm per layer.
   [5] The magnetoresistive effect element according to any one of [1] to [4],
wherein the Ir layer of the heavy-metal layer has a thickness equal to or greater than 0.6 nm and equal to or less than 1.5 nm per layer.
   [6] The magnetoresistive effect element according to any one of [1] to [5],
wherein the Pt layer and the Ir layer in the heavy-metal layer have a thickness ratio in a range of 1:0.5 to 1:0.8.
   [7] The magnetoresistive effect element according to [1],
wherein the heavy-metal layer is formed by stacking the Ir layer and the Pt layer one by one, a ferromagnetic layer is provided on a surface of the recording layer and another ferromagnetic layer is provided on an opposite surface of the recording layer.
   [8] The magnetoresistive effect element according to any one of [1] to [7],
wherein shapes of the recording layer, the tunnel barrier layer, and the reference layer viewed from a stack direction of the heavy-metal layer are asymmetrical to any line along a direction of a write current in the heavy-metal layer.
   [9] The magnetoresistive effect element according to any one of [1] to [7],
wherein shapes of the recording layer, the tunnel barrier layer, and the reference layer viewed from a stack direction of the heavy-metal layer are symmetrical to any one of lines along a direction of the write current in the heavy-metal layer.
   [10]. A magnetic memory,
wherein a plurality of the magnetoresistive effect elements, each of which includes the recording layer, the tunnel barrier layer, and the reference layer, according to any one of [1] to [9] is provided on the same heavy-metal layer.
   [11]. An artificial intelligence system,
wherein the magnetoresistive effect element according to any one of [1] to [7] is used for an electronic neuron to which a weighted sum of a resistive crossbar network is inputted.
   [12] The artificial intelligence system according to [11],
wherein the magnetoresistive memory element is used for a cross-point memory of a resistive crossbar network.

### Advantageous Effects of Invention

The present invention includes a heavy-metal layer formed by stacking an Ir layer and a Pt layer, a recording layer provided to be opposed to the heavy-metal layer and formed to include a first ferromagnetic layer having a reversible magnetization, a reference layer formed to include a second ferromagnetic layer in which the magnetization direction is fixed, and a tunnel barrier layer sandwiched between the first ferromagnetic layer and the second ferromagnetic layer and formed of an insulator, and thus, the magnetization direction in the first ferromagnetic layer can be reversed by a write current flowing in the heavy-metal layer.

### BRIEF DESCRIPTION OF DRAWINGS

FIG. 1 is a perspective view schematically illustrating a magnetoresistive effect element according to the first embodiment of the present invention.

FIG. 2 is a sectional view of the magnetoresistive effect element illustrated in FIG. 1.

FIG. 3 relates to a diagram for illustrating a method for writing data “0” into a magnetoresistive effect element that stores data “1” and illustrates an initial state of magnetization.

FIG. 4 relates to a diagram for illustrating a method for writing data “0” into a magnetoresistive effect element that stores data “1” and illustrates a state in which the data has been written by flowing a write current.

FIG. 5 relates to a diagram for illustrating a method for writing data “1” into a magnetoresistive effect element that stores data “0” and illustrates an initial state of magnetization.

FIG. 6 relates to a diagram for illustrating a method for writing data “1” into a magnetoresistive effect element that stores data “0” and illustrates a state in which the data has been written by flowing a write current.

FIG. 7 is a diagram for illustrating a method for reading data stored in a magnetoresistive effect element.

FIG. 8 is a timing chart of signals for writing data into a magnetoresistive effect element.

FIG. 9 is a sectional view of a magnetoresistive effect element according to the second embodiment of the present invention.

FIG. 10 is a view illustrating a rewrite progress in the magnetoresistive effect element in FIG. 9.

FIG. 11 is a sectional view of a magnetoresistive effect element according to the third embodiment of the present invention

FIG. 12 is a view illustrating a rewrite progress in the magnetoresistive effect element in FIG. 11.

FIG. 13 is a perspective view schematically illustrating a magnetoresistive effect element according to the fourth embodiment of the present invention.

FIG. 14 is a plan view of the third terminal illustrated in FIG. 13.

FIG. 15 is a perspective view schematically illustrating a magnetic memory according to the fifth embodiment of the present invention.

FIG. 16 is a diagram illustrating an outline of an AI system according to the sixth embodiment of the present invention.

FIG. 17 is an illustrated circuit diagram of an AI system for which a magnetoresistive effect element is used.

FIG. 18 is a diagram illustrating an outline of another AI system different from that shown in FIG. 17.

FIG. 19 is a plan view of an AI system according to the sixth embodiment of the present invention.

FIG. 20 is a plan view of another AI system according to the sixth embodiment of the present invention different from that shown in FIG. 19.

FIG. 21A is a sectional view of the first fabricated sample.

FIG. 21B is a sectional view of the second fabricated sample.

FIG. 21C is a sectional view of the third fabricated sample.

FIG. 21D is a sectional view of the fourth fabricated sample.

FIG. 21E is a sectional view of the fifth fabricated sample.

FIG. 21F is a sectional view of the sixth fabricated sample.

FIG. 21G is a sectional view of the seventh fabricated sample.

FIG. 21H is a sectional view of the eighth fabricated sample.

FIG. 21I is a sectional view of a fabricated comparison sample.

FIG. 21J is a sectional view of the ninth fabricated sample.

FIG. 22 is a diagram illustrating the heavy-metal layer thickness dependence of sheet conductance of the third sample.

FIG. 23 is a diagram illustrating the heavy-metal layer thickness dependence of sheet conductance of the fourth sample.

FIG. 24 is a diagram illustrating the heavy-metal layer thickness dependence of sheet conductance of the fifth sample.

FIG. 25 is the resistivity results calculated from the heavy-metal layer thickness dependence of sheet conductance of each sample.

FIG. 26 is a diagram illustrating the spin orbit torque efficiency θ_{SH} of each sample.

FIG. 27 is a diagram illustrating the spin Hall conductivity σ_{SH} of each sample.

FIG. 28 illustrates the spin orbit torque efficiency θ_{SH} for each film thickness ratio of Pt layer and Ir layer of each sample.

FIG. 29 illustrates resistivity ρₓₓ for each film thickness ratio of Pt layer and Ir layer of each sample.

FIG. 30 illustrates spin Hall conductivity σ_{SH} for each film thickness ratio of Pt layer and Ir layer in each sample.

FIG. 31 is a diagram illustrating the heavy-metal layer thickness dependence of sheet conductance of the ninth sample.

FIG. 32 is a diagram illustrating the heavy-metal layer thickness dependence of sheet conductance.

FIG. 33 illustrates the investigation results of magnetic coupling between the layers of Pt/Ir spacer of the tenth sample.

FIG. 34 is a diagram schematically illustrating a Hall bar and a measurement system that are fabricated as the eleventh sample.

FIG. 35A is a sectional view of the eleventh fabricated sample.

FIG. 35B is a sectional view of another fabricated sample for comparison.

FIG. 36 is a diagram illustrating the pulse current dependence of Hall resistivity of the eleventh sample and another comparison sample.

### DESCRIPTION OF EMBODIMENTS

The embodiments of the present invention will now be described in detail with reference to the drawings. Those described in the embodiments of the present invention can be appropriately modified without departing from the scope of the invention.

### First Embodiment

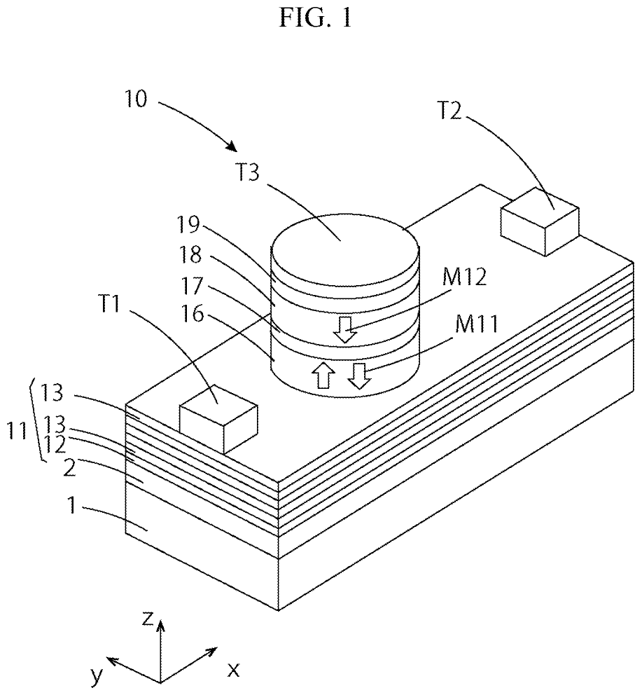

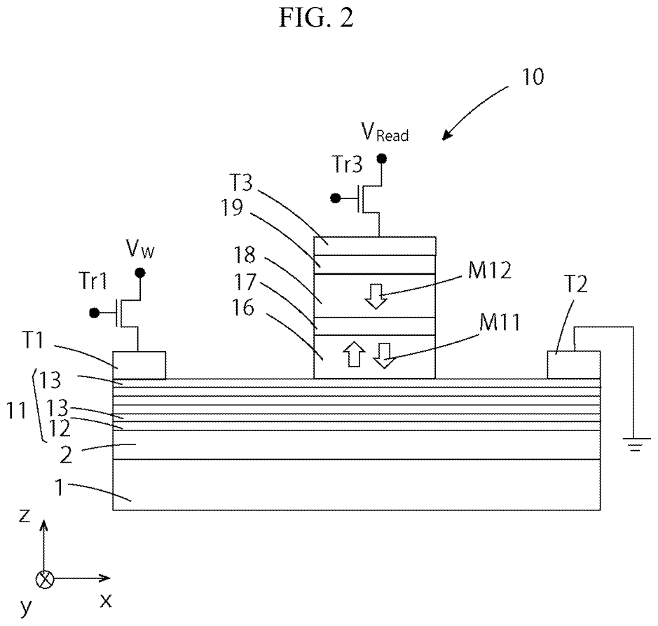

FIG. 1 is a perspective view schematically illustrating a magnetoresistive effect element 10 according to the first embodiment of the present invention; FIG. 2 is a sectional view of the magnetoresistive effect element 10 illustrated in FIG. 1. The magnetoresistive effect element 10 according to the first embodiment of the present invention includes: a heavy-metal layer 11, a recording layer 16, a tunnel barrier layer 17, and a reference layer 18. The recording layer 16 is provided to be opposed to the reference layer 18, that is, near the heavy-metal layer 11, with the tunnel barrier layer 17 interposed. The reference layer 18 is provided to be opposed to the heavy-metal layer 11 with the tunnel barrier layer 17 interposed. The recording layer 16, the tunnel barrier layer 17, and the reference layer 18 form a Magnetic Tunnel Junction (MTJ). The magnetoresistive effect element 10 uses spin-orbit torque (SOT) induced magnetization switching by a current flowing in the heavy-metal layer 11 (hereinafter, referred to as “a write current”) to form an MRAM (magnetic random access memory) element that inverts a magnetization direction in a first ferromagnetic layer of the recording layer 16.

The heavy-metal layer 11 is formed by stacking an Ir layer 12 and a Pt layer 13. The heavy-metal layer 11 is provided on a substrate 1, or on a buffer layer 2 provided on the substrate as needed. When the heavy-metal layer 11 is formed by stacking an Ir layer 12 and a Pt layer 13, the outermost Pt layer 13, that is, a Pt layer 13 most adjacent to the recording layer 16 in the stack direction, preferably forms an interface with the recording layer 16; because, in the heavy-metal layer 11, it is more preferable for any of spin Hall angle θ_{SH}, electrical resistivity ρ, and spin Hall conductivity σ_{SH} when one of the Pt layers 13 is provided most adjacent to the recording layer 16 than any of the Ir layers. The heavy-metal layer 11 may be formed by stacking an Ir layer 12 and a Pt layer 13. Also in this case, it is preferable that the Ir layer 12 is provided to be more adjacent to the substrate 1 and that the Pt layer 13 is provided to be more adjacent to the recording layer 16, that is, farther to the substrate 1. Otherwise, as shown in FIGS. 1 and 2, Ir layers 12 and Pt layers 13 can be repeatedly stacked one by one. When Ir layers 12 and Pt layers 13 are repeatedly stacked one by one, either one of the Ir layers 12 or one of the Pt layers 13 can be provided most adjacent to the substrate 1 or the buffer layer 2. That is, in the Ir layer 12 and the Pt layer 13 forming a part of the heavy-metal layer 11, the most adjacent to the recording layer 16 needs to be Pt layer 13.

When the Ir layers 12 and the Pt layers 13 are repeatedly stacked, each of the Pt layers 13 preferably has a thickness greater than 0.6 nm and equal to less than or 1.5 nm, and each of the Ir layers 12 preferably has a thickness equal to or greater than 0.6 nm and equal to or less than 1.5 nm. Here, the Ir layer 12 is a layer made of iridium (Ir), and the Pt layer 13 is a layer made of platinum (Pt). If at least one or two of the Ir layers 12 and the Pt layers 13 are stacked and the number of the stacked layers is adjusted such that the heavy-metal layer 11 as a whole has a thickness equal to or less than about 10 nm in total, for example, when 6 or 7 layers are stacked, it is sufficient to flow current.

The recording layer 16 is provided to include a first ferromagnetic layer having a reversible magnetization and to be in an opposing direction, for example, to contact a Pt layer 13 that is the outmost surface of the heavy-metal layer 11. The recording layer 16 has a thickness equal to or greater than 0.8 nm and equal to or less than 5.0 nm, preferably, equal to or greater than 1.0 nm and equal to or less than 3.0 nm. The recording layer 16 may be magnetized in a vertical direction with respect to the first ferromagnetic layer. For that reason, the recording layer 16 is configured to have a reversible magnetization in a vertical direction with respect to the film surface. Note that the meaning “magnetization in a vertical direction” includes that it may have a component of magnetization parallel to the film surface. The recording layer 16 may be magnetized in an in-plane direction with respect to the first ferromagnetic layer. For that reason, the recording layer 16 is configured to have a reversible magnetization in an in-plane direction with respect to the film surface. Also note that the meaning “magnetization in an in-plane direction” includes that it may have a component of magnetization vertical to the film surface. In order to generate an interface magnetic anisotropy in the recording layer 16, the recording layer 16, that is, the first ferromagnetic layer is configured with CoFeB, FeB, CoB, and so on. When magnetic shape anisotropy is used in a fine MTJ region, a single layer of CoFeB, FeB, CoB, each processed to have the longest length in a film thickness direction, may be used as a recording layer.

The tunnel barrier layer 17 is formed to oppose the first ferromagnetic layer of the recording layer 16. The tunnel barrier layer 17 is formed of insulating material, for example, MgO, Al₂O₃, AlN, MgAlO, and so on, especially, MgO is preferable. The tunnel barrier layer 17 has a thickness equal to or greater than 0.1 nm and equal to or less than 2.5 nm, preferably, equal to or greater than 0.5 nm and equal to or less than 1.5 nm.

The reference layer 18 may be configured of a single layer, as shown in FIGS. 1. and 2, or may have a three-layer stacked ferri-structure, for example, in which a ferromagnetic layer, a non-magnetic layer, and a ferromagnetic layer are stacked in this order. In this case, the magnetization direction in one ferromagnetic layer is anti-parallel to the magnetization direction in the other ferromagnetic layer. When the recording layer 16 is magnetized in the vertical direction, the magnetization in the one ferromagnetic layer is in −z direction and the magnetization in the other ferromagnetic layer is in +z direction. The recording layer 16 is magnetized in the in-plane direction, the magnetization in the one ferromagnetic layer is, for example, in −x direction and the magnetization in the other ferromagnetic layer is in +x direction. The magnetization direction in one and the other ferromagnetic layers may be in an xy-plane.

Materials and thickness of the second ferromagnetic layer of the reference layer 18 most adjacent to the tunnel barrier layer 17 is selected to generate an interface magnetic anisotropy on the interface between the second ferromagnetic layer of the reference layer 18, most adjacent to the tunnel barrier layer 17, and the tunnel barrier layer 17. Thus, the reference layer 18 having a stacked ferri-structure and an antiferromagnetic coupling of the magnetization in the one ferromagnetic layer of the reference layer 18 and that in the other ferromagnetic layer fixes the magnetization in the one ferromagnetic layer of the reference layer 18 and that in the other ferromagnetic layer in the vertical or in-plane direction. The antiferromagnetic coupling of the magnetization in the one ferromagnetic layer of the reference layer 18 and that in the other ferromagnetic layer may be fixed by an inter-layer coupling to fix the magnetization direction. Note that the layer in the reference layer 18 such as the second ferromagnetic layer in the reference layer 18 is formed of the same material as the recording layer 16, for example, ferromagnetic material.

As shown in FIG. 1, the recording layer 16, and the tunnel barrier layer 17, and the reference layer 18 form a cylindrical column. The shapes of the recording layer 16, the tunnel barrier layer 17, and the reference layer 18 viewed from a stack direction of the heavy-metal layer 11, that is, the shape in-plane view, is symmetrical to the center line of the circle. In other words, it is symmetrical to any line in the direction where a write current flows in the heavy-metal layer 11.

The cap layer 19, a layer of about 1.0 nm formed of conductive material such as Ta to prevent from oxidation, may be formed to be adjacent to the reference layer 18. In addition, the cap layer 19 may be formed of non-magnetic layer such as MgO. When a tunnel current flows through the cap layer 19, the current flows from the third terminal T3 to the reference layer 18.

A first terminal T1 and a second terminal T2 are respectively provided on either the top or the bottom of the heavy-metal layer 11, or one of the terminals is provided upwardly and the other downwardly, with an MTJ including a recording layer 16, a tunnel barrier layer 17, and a reference layer 18 in the middle. In a shown example, the first terminal T1 is provided on the heavy-metal layer 11 and the second terminal T2 is provided on the heavy-metal layer 11 to oppose the first terminal T1 with the MTJ including the recording layer 16, the tunnel barrier layer 17, and the reference layer 18 in the middle of those terminals. The first terminal T1 is connected to either a source or a drain of the first transistor Tr1 (FET); the other not connected to the source or the drain of the first transistor Tr1 is connected to the first bit line and to a power source (a write power source) that supplies a write voltage V_{W}; a gate of the first transistor Tr1 (FET) is connected to a word line. The second terminal T2 is connected to ground, for example. In this case, the second terminal T2 may be connected via a second transistor Tr2 (FET). The second terminal T2 may be connected to the second bit line via the second transistor Tr2. The direction in which a write current I_{W} is supplied may be changed according to the potential difference between the first terminal T1 and the second terminal T2. For example, when the first bit line is set to High and the second bit line is set to Low, the write current I_{W} flows from the first terminal T1 to the second terminal T2. On the other hand, when the first bit line is set to Low and the second bit line is set to High, the write current I_{W} flows from the second terminal T2 to the first terminal T1. When reading data, the second transistor Tr2 is turned OFF so that a read current does not flow into the second terminal T2.

The third terminal T3 is provided on the cap layer 19 to be contact with the cap layer 19. The third terminal T3 has a cylindrical columnar shape same as the recording layer 16, the tunnel barrier layer 17, and the reference layer 18. The third terminal T3 provided on a top surface of the cap layer 19 to cover the whole top surface is electrically connected with the reference layer 18 via the cap layer 19. The third terminal T3 is connected to either a source or a drain of the third transistorTr3 (FET). The source or the drain of the third transistorTr3 not connected to the third terminal T3 is connected to the third bit line and to a power source that supplies a read voltage V_{Read} (a read power source). A gate of the third transistor Tr3 is connected to a read-out voltage line. It is possible to stop power supply to the second terminal T2 by turning OFF the second transistor Tr2.

A method for writing data into a magnetoresistive effect element 10 shown in FIG. 1 will be described. In the magnetoresistive effect element 10, the resistance of the MTJ changes according to the parallel or anti-parallel of the magnetization directions of the first and second ferromagnetic layers, those layers are respectively included in the recording layer 16 and the reference layer 18 and adjacently contacted with the tunnel barrier layer 17. Therefore, depending on whether the magnetization direction is parallel or anti-parallel, 1-bit data of “0” or “1” is allocated to store data in the magnetoresistive element 10.

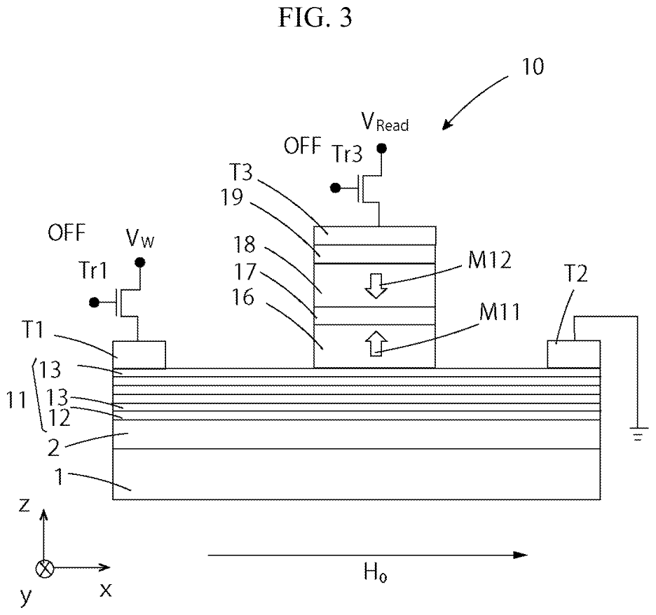

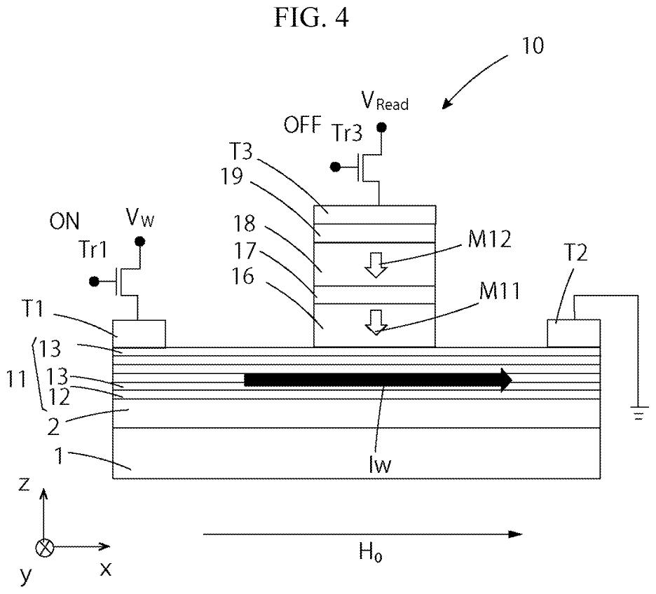

The following is a specific description. First, an example will be described: to write data “0” into the magnetoresistive effect element 10, in which data “1” is stored. In the initial state, as shown in FIG. 3, assuming that: the magnetoresistive element 10 stored data “1”; the magnetization direction M11 in the recording layer 16 is upward; the magnetization direction M12 in the reference layer 18 is downward; and the magnetization directions M11 and M12 are anti-parallel. Also, assuming that the first transistor Tr1 and the third transistor Tr3 are set to OFF. First, the external magnetic field H₀ is to be applied in the +x direction. In this state, the first transistor Tr1 is set to ON, and a write voltage V_{W} is applied to the first terminal T1. At this time, the write voltage V_{W} is set to be higher than the ground voltage, and thus, a write current I_{W} flows from the first terminal T1 to the second terminal T2 via the heavy-metal layer 11, and the write current I_{W} flows in the +x direction from the one end to the other end of the heavy-metal layer 11. The third transistor Tr3 is OFF, and thus, no current flows from the first terminal T1 to the third transistor T3 via the MTJ. The write current I_{W} is a pulse current, and by adjusting the time that the first transistor Tr1 is ON, the pulse width of the write current I_{W} can be changed. When the write current I_{W} flows in the heavy-metal layer 11, a spin current (flow of spin angular momentum) is generated by the spin Hall effect due to the spin-orbit interaction in the heavy-metal layer 11; spins in opposite directions to each other respectively flow in the ±z directions of the heavy-metal layer 11; and the spins are unevenly distributed in the heavy-metal layer 11. By the spin current flowing through the heavy-metal layer 11, spins oriented in one direction are absorbed in the recording layer 16. In the first ferromagnetic layer of the recording layer 16, the absorbed spins exert torque on the magnetization M11, the torque rotates the magnetization M11 to reverse its direction from upward to downward, and the magnetizations M11 and M12 become a parallel state. For example, when the external magnetic field H0 is applied in the +x direction, the torque exerted by the spins are canceled out, turning the magnetization M11 to the −z direction. Then, turning OFF the first transistor Tr1 to stop the write current I_{W}, the magnetization M11 is fixed in the −z direction and data “0” is stored. This state is shown in FIG. 4.

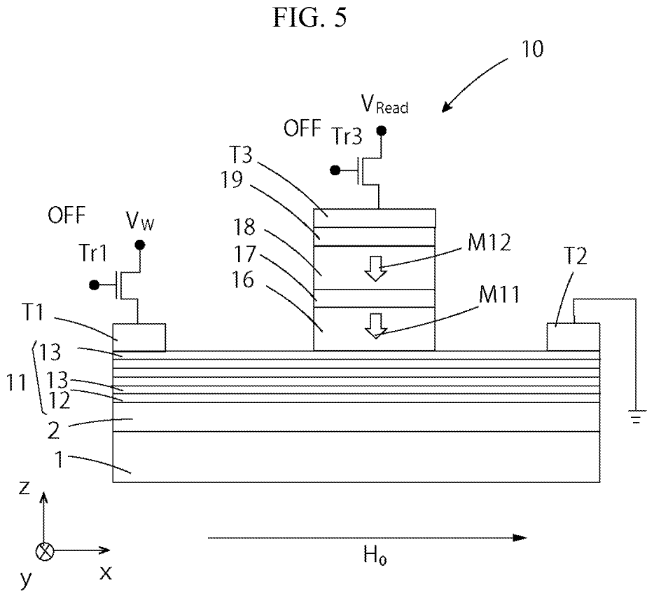

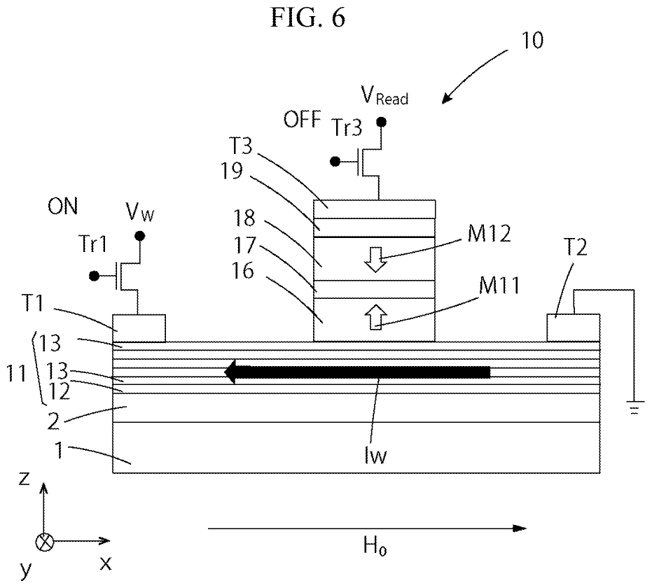

Next, an example will be described: to write data “1” into the magnetoresistive effect element 10, in which data “0” is stored. In the initial state, as shown in FIG. 5, assuming that: the magnetoresistive element 10 stores data “0”; the magnetization direction M11 in the recording layer 16 is downward; the magnetization direction M12 in the reference layer 18 is downward; and the magnetization direction M11 and M12 are parallel. Also, assuming that the first transistor Tr1 and the third transistor Tr3 are set to OFF. First, the external magnetic field H₀ is applied in the +x direction. In this state, the first transistor Tr1 is set to ON, and a write voltage V_{W} is applied to the first terminal T1. At this time, the write voltage V_{W} is set to be lower than the ground voltage, and thus, a write current I_{W} flows from the second terminal T2 to the first terminal T1 via the heavy-metal layer 11, and the write current I_{W} flows in the −x direction from the other end to the one end of the heavy-metal layer 11. The third transistor Tr3 is OFF, and thus, no current flows from the second terminal T2 to the third transistor T3 via the MTJ. The write current I_{W} is a pulse current, and by adjusting the time that the first transistor Tr1 is ON, the pulse width of the write current I_{W} can be changed. When the write current I_{W} flows in the heavy-metal layer 11, a spin current (flow of spin angular momentum) is generated by the spin Hall effect due to the spin-orbit interaction in the heavy-metal layer 11; spins in opposite directions to each other respectively flow in the ±z directions of the heavy-metal layer 11; and the spins are unevenly distributed in the heavy-metal layer 11. By the spin current flowing through the heavy-metal layer 11, spins oriented in one direction flow into the recording layer 16. In the first ferromagnetic layer of the recording layer 16, the flowing spins exert torque on the magnetization M11, the torque rotates the magnetization M11 to reverse its direction from downward to upward, and the magnetizations M11 and M12 become an anti-parallel state. For example, when the external magnetic field H₀ is applied in the +x direction, the torque exerted by the spins are canceled out, turning the magnetization M11 to the +z direction. Then, turning OFF the first transistor Tr1 to stop the write current I_{W}, the magnetization M11 is fixed in the +z direction and data “1” is stored. In this manner, a write current I_{W} flowing into the heavy-metal layer 11 inverts the magnetization in the recording layer 16, enabling data rewriting. This state is shown in FIG. 6.

In this manner, data “0” or data “1” can be written into the magnetoresistive effect element 10 by supplying a write current I_{W} between the one end and the other end of the heavy-metal layer 11 to reverse the magnetization direction in the recording layer 16.

Note that the magnetoresistive effect element 10 may be configured such that: a voltage is applied between the one end (first terminal T1) and the other end (second terminal T2) of the heavy-metal layer 11 to flow a write current through the heavy-metal layer 11; and another voltage is applied to the MTJ via the third terminal T3 to reduce the magnetic anisotropy of the ferromagnetic layer of the recording layer 16, thereby transferring spins from the heavy-metal layer 11 to reverse the magnetization M11 of the recording layer 16.

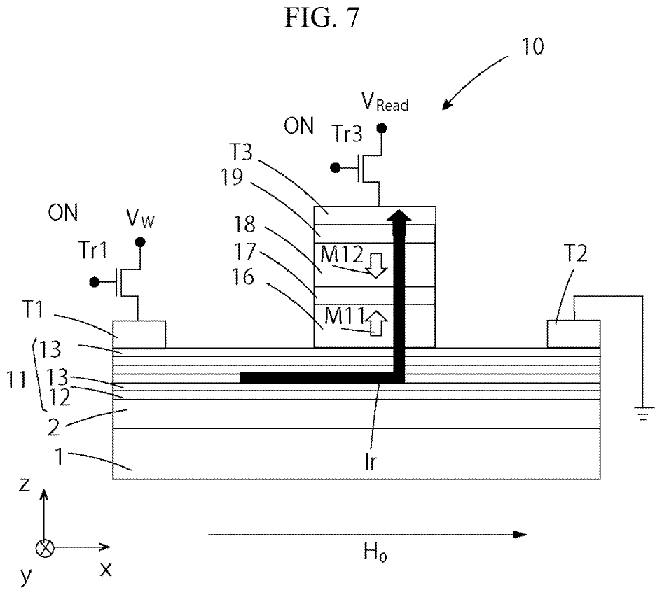

Next, a method for reading out data will be described with reference to FIG. 7. Here, the first transistor Tr1 and the third transistor Tr3 are set to OFF. First, setting a write voltage V_{W} higher than the read-out voltage V_{Read}; then, to read out data, turning ON the first transistor Tr1 and the third transistor Tr3 to apply the write voltage V_{W} to the first terminal T1, and to apply the read-out voltage V_{Read} to the third terminal T3. The write voltage V_{W} is set higher than the read-out voltage V_{Read}, and thus, the read-out current Iᵣ flows from the first terminal T1 to the heavy-metal layer 11, the recording layer 16, the tunnel barrier layer 17, the reference layer 18, the cap layer 19, and the third terminal T3 in the stated order. The read-out current Iᵣ flows through the tunnel barrier layer 17. The read-out current Iᵣ is detected by a detector (not shown). The value of the read-out current Iᵣ changes according to the resistance of the MTJ, and thus, the value Ir tells whether the MTJ is in the parallel state or the anti-parallel state, or in other words, it can be read whether the MTJ stores data “0” or data “1”. The read-out current Iᵣ is a pulse current, and by adjusting the time that the third transistor Tr3 is ON, the pulse width can be adjusted.

In this case, the read-out current Iᵣ is preferably set to be weak enough to prevent from a spin transfer magnetization reversal of the recording layer 16 due to the read-out current Iᵣ flowing through the MTJ. The value of the read-out current Iᵣ is adjusted by appropriately adjusting the potential difference between the write voltage V_{W} and the read-out voltage V_{Read}. Also, it is preferable that the third transistor Tr3 be turned ON to turn ON the read-out voltage V_{Read} after turning ON the first transistor Tr1 to turn ON the write voltage V_{W}. Because it enables suppression of the current flowing from the third terminal T3 to the second terminal T2 via the MTJ, leading to suppressing current other than the read-out current flowing into the MTJ.

Then, after turning OFF the third transistor Tr3, the first transistor Tr1 is turned OFF. Turning OFF the first transistor Tr1 after the third transistor Tr3, or in other words, turning OFF the write voltage V_{W} after the read-out voltage V_{Read} enables suppression of the current flowing from the third terminal T3 to the second terminal T2 via the MTJ and the heavy-metal layer 11 based on the potential difference between the read-out voltage V_{Read} and ground voltage. Thus, the magnetoresistive effect element 10 can: protect the tunnel barrier layer 17; make the tunnel barrier layer 17 thinner; and, furthermore, suppress the read disturbance in which the magnetization state of the recording layer 16 is changed by a current flowing through the MTJ.

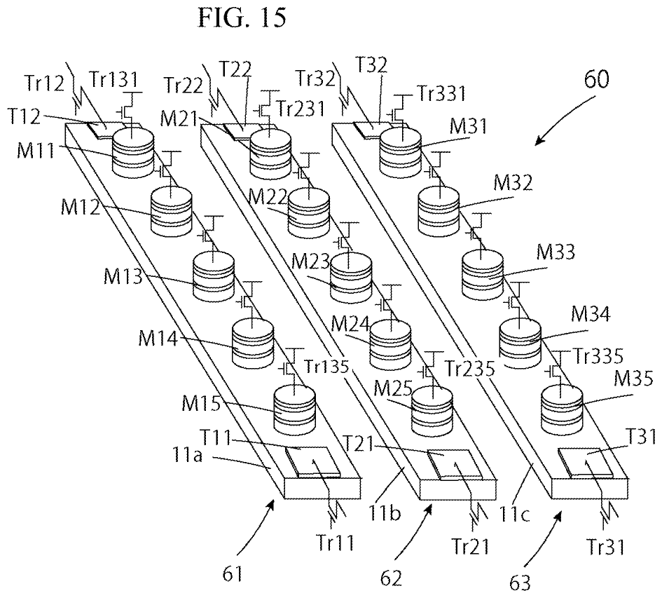

Another method for writing into the magnetoresistive element 10 according to the first embodiment will be described. Note that the description here is for the case applied to an artificial intelligence system, which will be described later. Thus, as shown in FIG. 15 (described later), assuming that: multiple MTJs, each consisting of a recording layer 16, a tunnel barrier layer 17 and a reference layer 18, are provided on the same heavy-metal layers 11a, 11b, and 11c; and, in the initial state, the first transistor connected to the first terminal T1 of the heavy-metal layer 11 and the third transistor Tr3 connected to the third terminal T3 of each MTJ are all set to OFF. If necessary, the third transistor Tr3 connected to the third terminal T3 is turned ON to reduce the magnetic anisotropy of the recording layer 16. The write voltage V_{W} is set to a positive voltage and the first transistor Tr11 connected to the first terminal T1 is turned ON to flow the write current I_{W} from the first terminal T1 to the second terminal T2. As a result, the recording layer 16 having a perpendicular magnetization rotates due to the MTJ having a low magnetic anisotropy constant and the axis of easy magnetization thereof cannot be settled in the stable direction. Next, the third transistors Tr3 connected to the third terminals T3 of the MTJs are all turned ON to flow a write supplement current I_{WA}; accordingly, data is written only in the area where the current flows. Then, the third transistors Tr3 connected to the third terminals T3 of the MTJs are all turned OFF and the first transistor Tr1 connected to the first terminal T1 is turned OFF.

Next, the write voltage V_{W} is set to a negative voltage and the first transistor Tr1 connected to the first terminal T1 is turned ON to flow the write current I_{W} from the second terminal T2 to the first terminal T1. When the magnetic anisotropy constant Δ of the recording layer 16 is set to a low value of 5 to 15 and the write current I_{W} is supplied therein, the recording layer 16 having a perpendicular magnetization rotates and the axis of easy magnetization thereof cannot be settled in the stable direction. Then, by turning ON the third transistor Tr3 connected to the third terminal T3 of the MTJ to select the MTJ into which data “1” is written, and by supplying the write supplement current I_{WA}, the recording layer 16 having the perpendicular magnetization is fixed in the direction in which the write supplement current I_{WA} flows, thereby inverting the axis of easy magnetization to be a stable state by spin transfer torque. When using this element as a cross-point memory of a crossbar network with the magnetic anisotropy constant α of the recording layer 16 set to a low value of 5 to 15 and with the write current I_{W} supplied therein, the recording layer 16 having the perpendicular magnetization rotates and the axis of easy magnetization thereof cannot be settled in the stable direction; accordingly, a wiring for applying a magnetic field, mentioned later, is used for writing. In this case, the magnetic anisotropy constant Δ of the recording layer 16 has a small value of 5 to 15, and thus, a small current magnetic field allows writing.

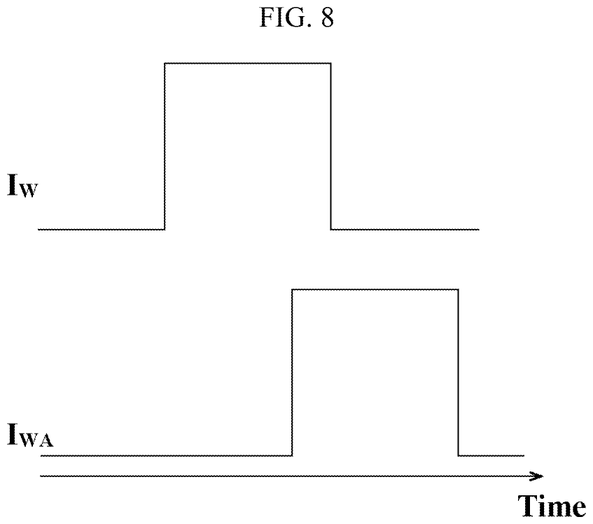

FIG. 8 is a timing chart of signals for writing data into the magnetoresistive effect element. The write current I_{W} and the write supplement current I_{WA} are signals. As shown in FIG. 8, the pulse of the write current I_{W} and the pulse of the write supplement current I_{WA} have timings such that at least some of them are temporally overlapped. As shown in FIG. 8, for example, the pulse of the write current I_{W} turns ON first, and the pulse of the write supplement current I_{WA} turns ON prior to the pulse of the write current I_{W} turning OFF. Then, the pulse of the write current I_{W} turns OFF, and the pulse of the write supplement current I_{WA} turns OFF.

Note that it may be configured to write the data “1” into all the MTJs simultaneously then write the data “0” only into the selected MTJs. The reading operation is performed by turning ON the transistor Tr1 connected to the first terminal T1, turning ON the transistor Tr3 connected to the third terminal T3 of the MTJ from which data is to be read, and then supplying the read-out current Iᵣ to the MTJ from which data is to be read. The reading method is the same as that in the first Embodiment.

The magnetoresistive effect element 10 according to the first embodiment of the present invention includes: a heavy-metal layer 11 formed by stacking Ir layer(s) 12 and Pt layer(s) 13; a recording layer 16 provided to be opposed to the heavy-metal layer 11, preferably provided on the uppermost surface of the Pt layer 13 in the heavy-metal layer 11, and including the first ferromagnetic layer having a reversible magnetization; a reference layer 18 formed to include the second ferromagnetic layer in which a magnetization direction is fixed; and a tunnel barrier layer 17 sandwiched between the first ferromagnetic layer and the second ferromagnetic layer, and formed of an insulator, therefore, a magnetization direction in the first ferromagnetic layer of the recording layer 16 can be efficiently reversed with a low resistance and without reducing reversal efficiency by a write current flowing in the heavy metal layer 11.

Note that it is possible not to use an external magnetic field by adjusting the configurations of the recording layer 16, the tunnel barrier layer 17, and the reference layer 18 in the in-plane view or adjusting the spin directions in the recording layer 16 and the reference layer 18. Furthermore, it is possible to be applied in any magnetization directions of the recording layer 16 and the reference layer 18 even though in-plane parallelly or in-plane vertically.

### Second Embodiment

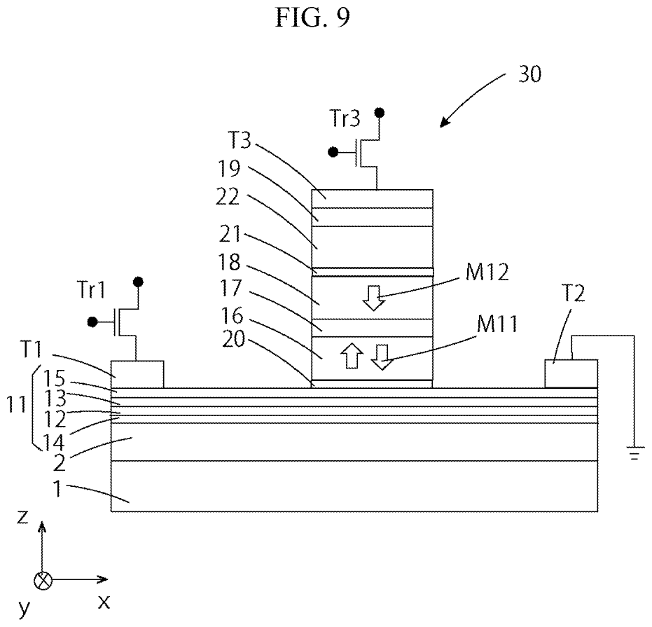

FIG. 9 is a sectional view of a magnetoresistive effect element 30 according to the second embodiment of the present invention. In the second embodiment, as shown in FIG. 9, a heavy-metal layer 11 is formed by stacking an Ir layer 12 and a Pt layer 13 which are provided between one ferromagnetic layer 14 and the other ferromagnetic layer 15. At that time, both the magnetization M21 of the one ferromagnetic layer 14 and the magnetization M22 of the other ferromagnetic layer 15 are in opposite directions. That is, when the element is configured to have a buffer layer 2 on the substrate 1 as required and the heavy-metal layer 11 thereon, one ferromagnetic layer 14 is provided more adjacent to the substrate 1 or the buffer layer 2 and the other ferromagnetic layer 15 is provided more adjacent to the recording layer 16. The reason for one by one provision of the Ir layer 12 and the Pt layer 13 is to antiferromagnetically couple the one ferromagnetic layer 14 and the other ferromagnetic layer 15.

In the second embodiment, when both the one ferromagnetic layer 14 and the other ferromagnetic layer 15 are perpendicularly magnetized layers such as Co, the recording layer 16 and the reference layer18 are preferably perpendicularly magnetized layers as well.

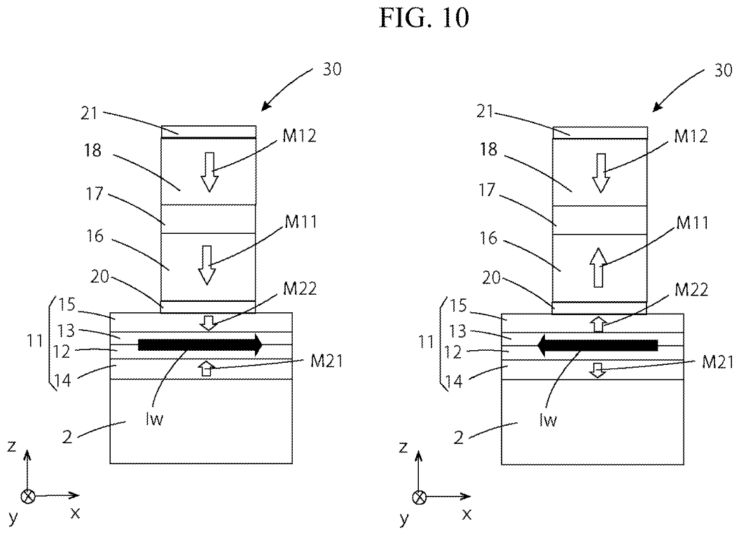

In the second embodiment, when current flows to one ferromagnetic layer 14, the other ferromagnetic layer 15, and the heavy-metal layer 11, especially, to the stack of the Ir layer 12 and the Pt layer 13, the magnetization of the one ferromagnetic layer 14 and the other ferromagnetic layer 15 are reversed due to the spin Hall effect; in the consequence of the reverse of the one ferromagnetic layer 14 and the other ferromagnetic layer 15, the recording layer 16 is magnetically reversed. As shown in the left side of FIG. 10, when a write current I_{W} flows in +x direction, the magnetization M21 of the one ferromagnetic layer 14 and the magnetization M22 of the other ferromagnetic layer 15 are reversed, and thus, the direction of the magnetization M11 of the recording layer 16 is reversed. In this state, when the write current I_{W} flows in −x direction, the magnetization M21 of the one ferromagnetic layer 14 and the magnetization M22 of the other ferromagnetic layer 15 are reversed, and thus, the direction of the magnetization M11 of the recording layer 16 is reversed as shown in the right side of FIG. 10.

Here, preferable thicknesses of the Ir layer 12 and the Pt layer 13 of the heavy-metal layer 11 will be described. For example, when both the one ferromagnetic layer 14 and the other ferromagnetic layer 15 are formed of Co, the Pt layer 13 preferably has a thickness equal to or greater than 0.6 nm and equal to or less than 1.0 nm, and in this case, the Ir layer 12 has a thickness preferably equal to or greater than 0.45 nm and equal to or less than 0.65 nm, equal to or greater than 1.3 nm and equal to or less than 1.5 nm. Because the one ferromagnetic layer 14 and the other ferromagnetic layer 15 are antiferromagnetically coupled. Both the one ferromagnetic layer 14 and the other ferromagnetic layer 15 have a thickness preferably equal to or less than 1 nm.

The magnetoresistive effect element 30 according to the second embodiment includes: a heavy-metal layer 11 formed by stacking an Ir layer 12 and a Pt layer 13 which are provided between one ferromagnetic layer 14 and the other ferromagnetic layer 15; a recording layer 16 including a first ferromagnetic layer with a reversible magnetization provided to be opposed to the heavy-metal layer 11 and more adjacent to the Pt layer 13 via the other ferromagnetic layer 15; a reference layer 18 including a second ferromagnetic layer of which magnetization direction is fixed; and a tunnel barrier layer 17 sandwiched between the first ferromagnetic layer and the second ferromagnetic layer and formed of an insulator, and thus, a write current flowing in the heavy-metal layer 11 can efficiently reverse both magnetization directions of one ferromagnetic layer 14 and the other ferromagnetic layer 15 which are respectively upper and lower layers of the heavy-metal layer 11 with a low resistance and without reducing the reverse efficiency, enabling a reverse of the magnetization direction of the first ferromagnetic layer of the recording layer 16.

Note that a first non-magnetic layer 20 is provided between the heavy-metal layer 11 and the recording layer 16, as shown in FIGS. 9. and 10, to divide a crystal structure of the heavy-metal layer 11 and the recording layer 16. Further, a second non-magnetic layer 21 is provided on a second ferromagnetic layer of the reference layer 18 adjacent to the tunnel barrier layer 17 to be opposite to the tunnel barrier layer 17 to divide a crystal structure of upper and lower layers of the second non-magnetic layer 21. One or more element is selected for the first non-magnetic layer 20 and second non-magnetic layer 21 among W, Ta, Mo, Hf, and so on.

Furthermore, as shown in FIG. 9, an anchoring layer 22 including (Co/Pt)ₙ/Ir/(Co/Pt)ₘ, for example, is provided to be opposite to the second ferromagnetic layer via the second non-magnetic layer 21 to fix and pin the direction of the magnetization M12 of the second ferromagnetic layer of the reference layer 18. In this case, the second ferromagnetic layer included the anchoring layer 22 may be referred to as the reference layer. Note that above-described m and n can be any natural number.

### Third Embodiment

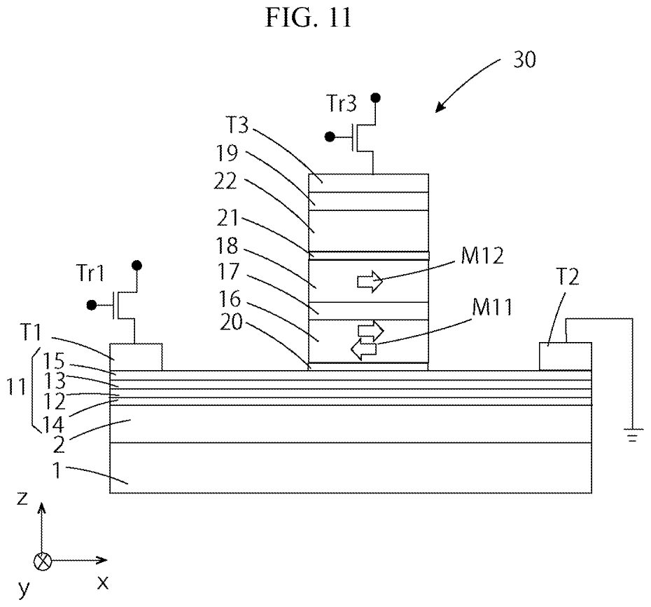

FIG. 11 is a sectional view of a magnetoresistive effect element 30 according to the third embodiment of the present invention. Also in the third embodiment, in the same way as the second embodiment, a heavy-metal layer 11 is formed by stacking an Ir layer 12 and a Pt layer 13 which are provided between one ferromagnetic layer 14 and the other ferromagnetic layer 15. At that time, both the magnetization M21 of the one ferromagnetic layer 14 and the magnetization M22 of the other ferromagnetic layer 15 are in opposite directions. Specifically, if the element is configured to have a buffer layer 2 on the substrate 1 as required and a heavy-metal layer 11 thereon, one ferromagnetic layer 14 is provided more adjacent to the substrate 1 or buffer layer 2 and the other ferromagnetic layer 15 is provided more adjacent to the recording layer 16. The reason for one by one provision of the Ir layer 12 and the Pt layer 13 is to antiferromagnetically couple the one ferromagnetic layer 14 and the other ferromagnetic layer 15.

In the third embodiment, when both the one ferromagnetic layer 14 and the other ferromagnetic layer 15 are horizontally magnetized layers such as CoFeB, the recording layer 16 and the reference layer 18 are preferably horizontally magnetized layers as well.

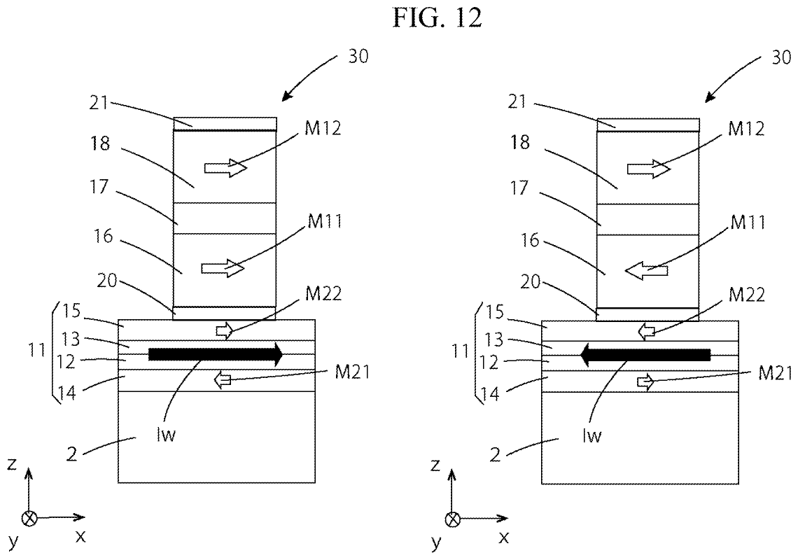

In the third embodiment, when current flows to one ferromagnetic layer 14 and the other ferromagnetic layer 15 and the heavy-metal layer 11, especially, the stack of the Ir layer 12 and the Pt layer 13, the magnetization of the one ferromagnetic layer 14 and the other ferromagnetic layer 15 are reversed due to the spin Hall effect; in the consequence of the reverse of the one ferromagnetic layer 14 and the other ferromagnetic layer 15, the recording layer 16 is magnetically reversed. As shown in the left side of FIG. 12, when a write current I_{W} flows in +x direction, the magnetization M21 of the one ferromagnetic layer 14 and the magnetization M22 of the other ferromagnetic layer 15 are reversed, and thus, the direction of the magnetization M11 of the recording layer 16 is reversed. In this state, when the write current I_{W} flows in −x direction, the magnetization M21 of the one ferromagnetic layer 14 and the magnetization M22 of the other ferromagnetic layer 15 are reversed, and thus, the direction of the magnetization M11 of the recording layer 16 is reversed as shown in the right side of FIG. 12.

Here, the preferable thickness of the Ir layer 12 and the Pt layer 13 of the heavy-metal layer 11 is the same as that in the second embodiment. Furthermore, as shown in FIG. 11, an anchoring layer 22 including (Co/Pt)ₙ/Ir/(Co/Pt)ₘ, for example, is provided to be opposite to the second ferromagnetic layer via the second non-magnetic layer 21 to fix and pin the direction of the magnetization M12 of the second ferromagnetic layer of the reference layer 18. In this case, the layers included second ferromagnetic layer and the anchoring layer 22 may be referred to as the reference layer. Note that above-described m and n can be any natural number.

The magnetoresistive effect element 30 according to the third embodiment includes: a heavy-metal layer 11 formed by stacking an Ir layer 12 and a Pt layer 13 which are provided between one ferromagnetic layer 14 and the other ferromagnetic layer 15; a recording layer 16 including a first ferromagnetic layer with a reversible magnetization provided to be opposed to the heavy-metal layer 11 and more adjacent to the Pt layer 13 via the other ferromagnetic layer 15; a reference layer 18 including a second ferromagnetic layer of which magnetization direction is fixed; and a tunnel barrier layer 17 sandwiched between the first ferromagnetic layer and the second ferromagnetic layer and formed of an insulator, and thus, a write current flowing in the heavy-metal layer 11 can efficiently reverse both magnetization directions of one ferromagnetic layer 14 and the other ferromagnetic layer 15 which are respectively upper and lower layers of the heavy-metal layer 11 with a low resistance and without reducing the reverse efficiency, enabling a reverse of the magnetization direction of the first ferromagnetic layer of the recording layer 16.

### Fourth Embodiment

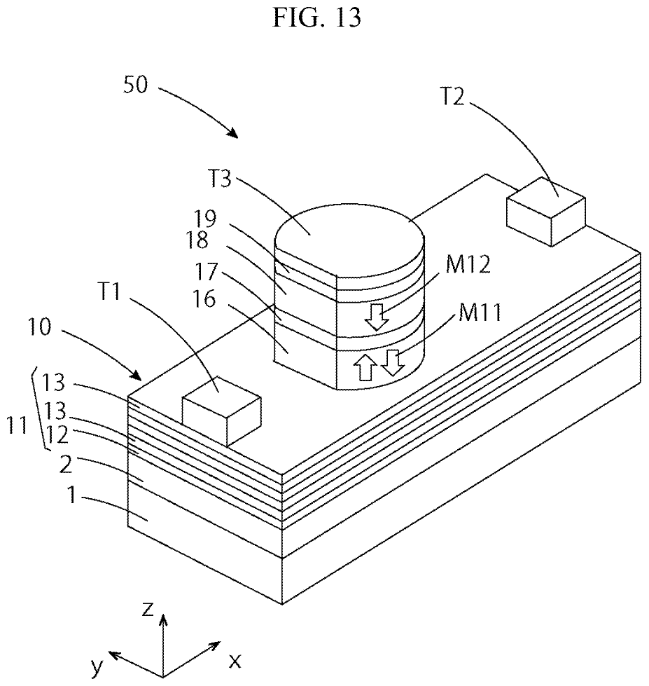

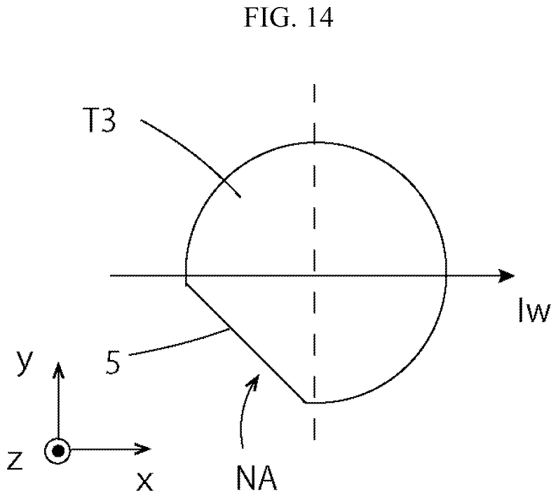

FIG. 13 is a perspective view schematically illustrating a magnetoresistive effect element 50 according to the fourth embodiment. FIG. 14 is a plan view of the third terminal illustrated in FIG. 13. The magnetoresistive effect element 50 according to the fourth embodiment is different from the magnetoresistive effect element 10 according to the first embodiment in the following points; specifically, the recording layer 16, the tunnel barrier layer 17, and the reference layer 18 are not shaped into cylindrical columns and each has a cutout section NA that is cut out at the surface inclining x and y axes and extending along z axis. Thus, shapes of the recording layer 16, the tunnel barrier layer17, and the reference layer 18 viewed from the stack direction of the heavy-metal layer 11, that is, the shapes in in-plane view, are asymmetrical to any line with respect to the direction of the write current flowing in the heavy-metal layer 11. Providing the cutout section NA leads to determination of the direction in which a precession is easily excited. And the magnetization direction of the recording layer 16 can be reversed and maintained without applying an external magnet field. Note that materials of the MTJ including the recording layer 16, the tunnel barrier layer 17, the reference layer 18, the cap layer 19, the terminal, and so on, and their thickness are same as those in the first embodiment. Further, they are applied not only to the first embodiment but also to the second and the third embodiments.

### Fifth Embodiment

The magnetic memory 60 according to the fifth embodiment of the present invention will be described in detail. FIG. 15 is a perspective view schematically illustrating a magnetic memory 60 according to the fifth embodiment of the present invention. The magnetic memory 60 according to the fifth embodiment, unlike the first to fourth embodiments, has a configuration in which a plurality of magnetoresistive effect elements are arranged in an array form on either surfaces of the same heavy-metal layer 11a, in the illustrated figure, on the heavy-metal layer 11a, 11b, 11c. As shown in FIG. 15, multiple magnetoresistive effect elements, for example, M11, M12, M13, M14, and M15, five magnetoresistive effect elements in total are arranged on one heavy-metal layer 11a to be one unit 61. Each of the magnetoresistive effect element M11 to M15 has a configuration where the recording layer 16, the tunnel barrier layer17, the reference layer 18, the cap layer19, and terminal is stacked in this order. In the one unit 61, a first common terminal (not shown) and a second common terminal (not shown) are provided on the heavy-metal layer 11 with the multiple magnetoresistive effect elements M11 to M15 in between; the first common terminal is connected to either a source or a drain of a first transistor Tr11 so that a write voltage can be applied; and the second common terminal is connected to either a source or a drain of a second transistor Tr12, for example, connected to ground.

In the magnetic memory 60 according to the fifth embodiment of the present invention as well, as described in the first embodiment with reference to FIGS. 1 and 2, each magnetoresistive effect element M11, M12, M13, M14, and M15 includes: a heavy-metal layer 11a, a recording layer 16, a tunnel barrier layer 17, and a reference layer 18; the recording layer 16 is provided to be opposite to the reference layer 18 via the tunnel barrier layer17, that is, more adjacent to the heavy-metal layer 11a; and the reference layer 18 is provided to be opposite to the heavy-metal layer 11a via the tunnel barrier layer17. The recording layer 16, the tunnel barrier layer17, and the reference layer 18 form a Magnetic Tunnel Junction (MTJ). The magnetoresistive effect elements M11, M12, M13, M14, and M15 use spin-orbit torque induced magnetization switching by a current flowing in the heavy-metal layer 11a (hereinafter, referred to as “a write current”) to invert the magnetization direction in the first ferromagnetic layer of the recording layer 16. In the same manner as the first embodiment, the recording layer 16, the tunnel barrier layer 17, and the reference layer 18 form a cylindrical columnar shape conforming to the shape of the recording layer 16 symmetrical around the direction in an in-plane view (z direction). That is, the recording layer 16, the tunnel barrier layer 17, and the reference layer 18 are line-symmetrical with respect to any line in the direction of current flow in the heavy-metal layer 11a. This is also same in units 62 and 63, which will be described later.

Further, as shown in FIG. 15, in the magnetic memory 60 according to the fifth embodiment, a plurality of magnetoresistive effect elements, for example, M21, M22, M23, M24, and M25, five magnetoresistive effect elements in total are arranged on one heavy-metal layer 11b to be one unit 62 and another multiple magnetoresistive effect elements, for example, M31, M32, M33, M34, and 35, five magnetoresistive effect elements in total are arranged on one heavy-metal layer 11c to be one unit 63. Each of the magnetoresistive effect element M21 to M25 and M31 to M35 has a configuration where the recording layer 16, the tunnel barrier layer 17, the reference layer 18, the cap layer 19, and terminals are stacked in this order. In each of the unit 62 and 63, a first common terminal (not shown) and a second common terminal (not shown) are correspondingly provided on the heavy-metal layer 11b or 11c with multiple magnetoresistive effect elements M21 to M25 or M31 to M35 in between; each first common terminal is connected to either a source or a drain of a first transistor Tr21, Tr31 so that a write voltage can be applied; and each second common terminal is connected to either a source or a drain of a second transistor Tr22, Tr32, for example, connected to ground. Magnetic memory is assembled by arranging units 61, 62, and 63 side by side. The fifth embodiment relates to the magnetoresistive effect element with an array of 5×3, as shown in the figure; however, it is not limited to this case and applicable to a magnetoresistive effect element with an array of m×n.

The magnetic memory 60 according to the fifth embodiment has a writing unit (not shown) provided with a writing power source to write data into magnetoresistive effect elements M11 to M35. The writing unit supplies a write current I_{W} to the heavy metal layers 11a, 11b, and 11c to write data into the magnetoresistive effect elements M11 to M53.

The magnetic memory 60 has a read-out unit provided with a read-out power source and a current detector (both are not shown) to read data from the magnetoresistive effect elements M11 to M35. The read-out power source supplies a read-out current Iᵣ flowing through the tunnel barrier layer 17. The current detector detects the read-out current Iᵣ flowing through the tunnel barrier layer 17 and reads data written in the magnetoresistive effect elements M11 to M35.

A method for writing data into magnetoresistive effect elements M11 to M35 will be described. The description is for a case where the second common terminals T12, T22, and T32 of the heavy-metal layers 11a, 11b, and 11c are respectively connected to the ground; each may be connected to ground via the respective second transistors Tr12, Tr22, and Tr32. As an initial state, assuming that: the first transistors Tr11, Tr21, and Tr31 connected to the first common terminals T11, T21, and T31 of the heavy-metal layers 11a, 11b, and 11c; and the third transistors Tr131 to Tr135, Tr231 to Tr235, and Tr331 to Tr335 connected to the third terminals T131 to T135, T231 to T 235, and T331 to T335 of each MTJ; all are turned OFF. First, the third transistors Tr131 to Tr135, Tr231 to Tr235, and Tr331 to Tr335 connected to the third terminals T131 to T135, T231 to T235, and T331 to T335 of each MTJ are all turned ON to reduce the magnetic anisotropy of the recording layers 16 of each MTJ. Next, the write voltage V_{W} is set to a positive voltage; the first transistors Tr11, Tr21, and Tr31 connected to the first common terminals T11, T21, and T31 are turned ON; and the write currents I_{W} flow from the first common terminals T11, T21, and T31 to the second common terminals T12, T22, and T32. As a result, data “0” is written into all MTJs simultaneously. Then, the third transistors Tr131 to Tr135, Tr231 to Tr235, and Tr331 to Tr 335 connected to the third terminals T131 to T135, T231 to T235, and T331 to T335 of each MTJ are all turned OFF; and the first transistors Tr11, Tr21, and Tr31 connected to the first common terminals T11, T21, and T31 are turned OFF.

Next, an MTJ is selected to be written into data “1” and its third transistor (for example, Tr131 connected to the third terminal T131) is turned ON. Then, the write voltage V_{W} is set to a negative voltage, the first transistor Tr11 connected to the first common terminal T11 is turned ON, and the write current I_{W} is supplied from the second common terminal T12 to the first common terminal T11. Only in the MTJ in which the third transistor Tr131 connected to the third terminal T131 is turned ON, a recording layer 16 has a low magnetic anisotropy; and thus, the magnetization is reversed. As a result, data “1” is written into only the selected MTJ. Then, the turned ON third transistor (Tr131, in this case) is turned OFF; and the first transistor Tr11 connected to the first common terminal T11 is turned OFF, thereby completing a writing operation.

Note that a configuration may alternatively be adopted in which data “1” is simultaneously written into all the MTJs and then data “0” is written only into the selected the MTJ. The reading operation is performed by turning ON the first transistor connected to the first common terminal of the MTJ with data for reading (for example, Tr11); turning ON the third transistor connected to the third terminal of the MTJ with data for reading (for example, Tr132); and then supplying the read-out current Iᵣ to the MTJ with data for reading. The reading operation thereafter is the same as the first embodiment.

The magnetic memory 60 according to the fifth embodiment of the present invention includes: a recording layer 16 formed by stacking an Ir layer 12 and a Pt layer 13 and including a first ferromagnetic layer with reversible magnetization provided to be opposed to the heavy-metal layer 11 via the ferromagnetic layer 15; a reference layer 18 including a second ferromagnetic layer of which magnetization direction is fixed; and a tunnel barrier layer 17 sandwiched between the first ferromagnetic layer and the second ferromagnetic layer and formed of an insulator, and thus, a write current flowing in the heavy-metal layer 11 reverses magnetization directions of one ferromagnetic layer 14 and the other ferromagnetic layer 15 provided on and below the heavy-metal layer 11, enabling the magnetization direction of the first ferromagnetic layer.

In particular, as the resistivity of the heavy-metal layers 11a, 11b, and 11c becomes low, voltage drop between the first common terminal T11, T21, and T31 and their corresponding second common terminal T21, T22, and T23 due to so called interconnection resistance is reduced, accordingly, voltages applied to be each MTJ provided either on or below the same heavy-metal layer 11a, 11b, and 11c would be approximately the same. Further, it leads to reduction of number limit of the magnetoresistive effect element to be provided on the same heavy-metal layer, thereby expanding the design possibility.

As described above, the fifth embodiment is not limited to the case where a plurality of magnetoresistive effect elements according to a first embodiment is provided on the same heavy-metal layer 11a, 11b, and 11c. Like the second embodiment and the third embodiment, the heavy-metal layer 11 may be configured to include: a stack of Ir layer 12 and a Pt layer 13 between one ferromagnetic layer 14 and the other ferromagnetic layer 15; and a plurality of magnetoresistive effect elements, each element including the recording layer 16, the tunnel barrier layer 17 and the reference layer 18 those are provided on the same heavy metal layer 11a, 11b and 11c. Further, the MTJ is not limited to be shaped into a cylindrical columnar; it may have a cutout section NA like the fourth embodiment.

### Sixth Embodiment

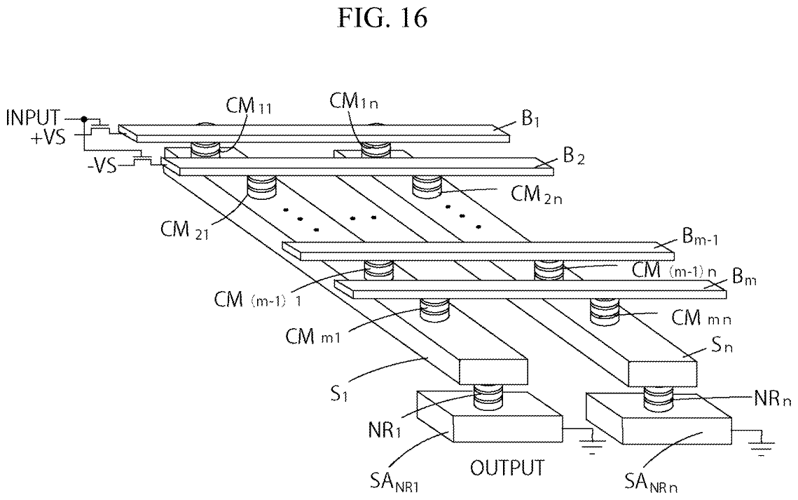

FIG. 16 is a diagram illustrating an outline of an AI system according to the sixth embodiment of the present invention. A plurality of first wiring lines (S₁, . . . , Sₙ) extending in one direction and a plurality of second wiring lines (B₁, . . . , Bₘ) extending in a direction perpendicular to the one direction are provided, and at each intersection point between the first wiring lines (S₁, . . . , Sₙ) and the second wiring lines (B₁, . . . , Bₘ), a cross-point memory (CM₁₁, . . . , CMₘₙ) connected to each of the first wiring lines (S₁, . . . Sₙ) and second wiring lines (B₁, . . . , Bₘ) is provided. Each of the cross-point memories (CM₁₁, . . . , CMₘₙ) is constituted of a storage element such as a ReRAM (resistance change memory), a PCM (phase-change memory), or an MTJ. Thus, a resistive crossbar network is provided.

An input line INPUT is connected to one end of first wiring lines (S₁, . . . , Sn), and an electronic neuron (NR₁, . . . , NRₙ) is connected to the other end of the first wiring lines. The electronic neurons (NR₁, . . . , NRₙ) are formed on neuron substrates (SA_{NR1}, . . . , SANRₙ). The neuron substrates (SA_{NR1}, . . . , SANRₙ) are stacks, each of which includes a substrate 1, a buffer layer 2, and a heavy-metal layer 11. The electronic neurons (NR₁, . . . , NRₙ) are similar in configuration to the magnetoresistive effect element according to the embodiments 1 to 4 of the present invention. The neuron substrates (SA_{NR1}, . . . , SANRₙ) are connected to an output line OUTPUT.

The magnetoresistive effect element 10 according to the embodiments 1 to 4 of the present invention is used for each of the electronic neurons (NR₁, . . . , NRₙ) to which the weighted sum of the resistive crossbar network is inputted. The artificial intelligence systems (AI) includes a plurality of resistor crossbar network connected in multistage and is configured such that the output of a prior stage is inputted to the subsequent stage. The cross-point memories (CM₁₁, . . . , CMₘₙ) correspond to synapses of the AI system.

The cross-point memories (CM₁₁, . . . , CMₘₙ) store data regarding memories corresponding to a pair of the second wiring lines as one set of memories. If there is an input from a prior stage resistive crossbar network, for example, then VS is inputted to a second wiring line B₁ according to the input, and −VS is inputted to the second wiring line B₂. Accordingly, data is stored in the cross-point memory CM₁₁ and the cross-point memory CM₂₁. In cross-point memories following the cross-point memory CM₃₁ and the cross-point memory CM₄₁ as well, data is stored according to an input from a prior stage resistive crossbar network. The cross-point memories (CM₁₁, . . . , CMₘ₁) are provided on the same first wiring line S₁, and a signal of the weighted sum of data stored in the cross-point memories (CM₁₁, . . . , CMₘ₁), that is, a signal corresponding to the sum of read-out currents from the respective cross-point memories (CM₁₁, . . . , CMₘ₁), is outputted to an electronic neuron NR₁ and stored. In other second wiring lines Bₘ as well, data is likewise stored in the cross-point memories (CM₁ₘ, . . . , CMₘₘ) according to an input from a prior stage resistive crossbar network, and a signal of the weighted sum of data stored in the cross-point memories (CM₁ₘ, . . . , CMₘₘ) is outputted to the electronic neurons NRₙ and stored. The system is configured such that the data stored in the electronic neurons (NR₁, . . . , NRₙ) is inputted to a subsequent stage resistive crossbar network.

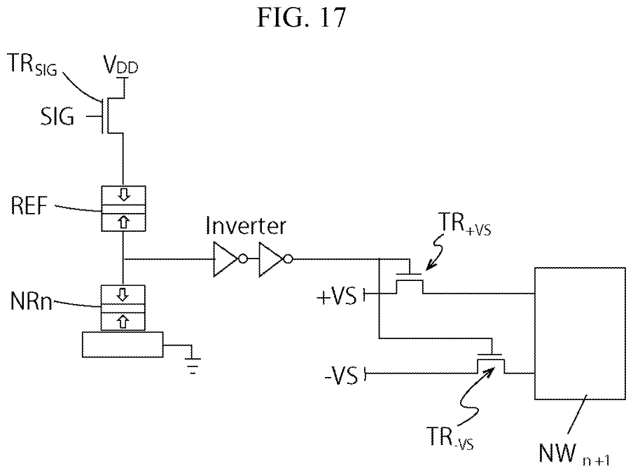

FIG. 17 is an illustrated circuit diagram of an AI system for which a magnetoresistive effect element is used. A reference element REF is connected in series to the electronic neuron NRₙ from which data is to be read. The reference element REF is constituted of a magnetoresistive effect element similar to the electronic neuron NRₙ and has a prescribed resistance. A power source voltage V_{DD} is inputted to the reference element REF via a transistor TR_{SIG}, and the electronic neuron NRₙ is connected to ground. When a read-out allowance signal SIG is inputted to turn ON the transistor TR_{SIG}, the power source voltage V_{DD} is inputted to the reference element REF.

In this configuration, when the electronic neuron NRₙ stores data “1” and is in a high resistance state, the output from the connection point between the electronic neuron NRₙ and the reference element REF reaches a high potential; the high potential signal is inputted via two inverters in series to a transistor TR_{+VS} and a transistor TR₋ᵥₛ; and a +VS signal and a −VS signal are inputted to a subsequent stage resistive crossbar network NWn+1.

In this configuration, when the electronic neuron NRₙ stores data “0” and is in a low resistance state, the output from the connection point between the electronic neuron NRₙ and the reference element REF reaches a low potential; the low potential signal is inputted via two inverters in series to the transistor TR_{+VS} and the transistor TR_{-VS}. As a result, the +VS signal and the −VS signal are not inputted to the subsequent stage resistive crossbar network NWn+1.

As described above, the magnetoresistive effect elements according to the embodiments of the present invention are used such that an output from a prior stage resistive crossbar network is inputted to the subsequent stage resistive crossbar network, thereby constituting the AI system.

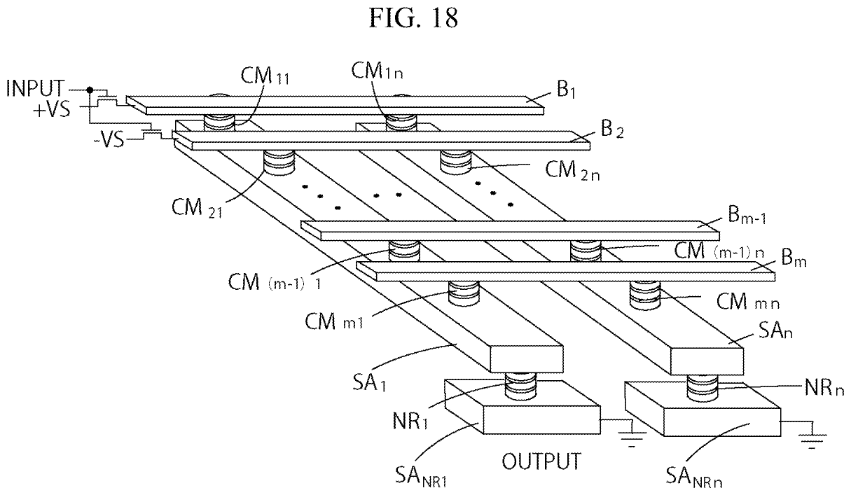

FIG. 18 is a diagram illustrating an outline of another AI system different from that shown in FIG. 17. The electronic neurons (NR1, . . . , NRn) have a similar configuration to the magnetoresistive effect element according to the embodiment of the invention. The cross-point memories (CM11, . . . , CMmn) also have the same configuration as described above. The first wiring lines to which the cross-point memories (CM11, . . . , CMmn) are provided are the common substrates (SA₁, . . . , SAₙ) and are constituted of a stack including a substrate 1, a buffer layer 2, and a heavy-metal layer 11. In this manner, magnetoresistive effect elements of the embodiment of the present invention are used such that an output from a prior stage resistive crossbar network is inputted to the subsequent stage resistive crossbar network, thereby constituting the AI system.

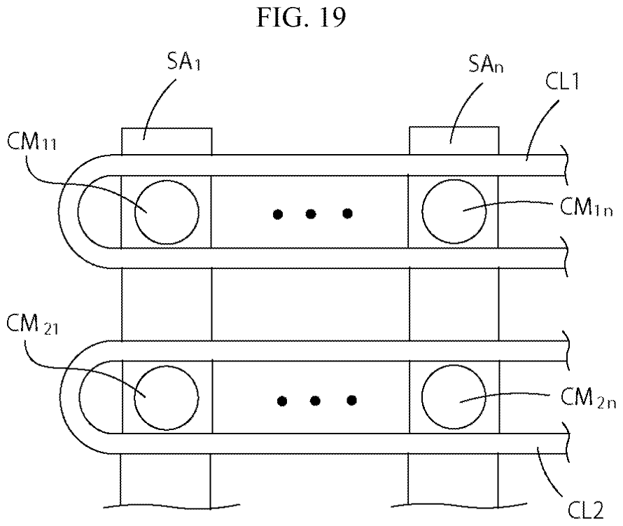

FIG. 19 is a plan view of an AI system according to the sixth embodiment of the present invention. An array of the magnetoresistive effect elements constituting the AI system may be provided with magnetic field application electrodes (CL1, CL2, . . . ) that can select a prescribed row and apply a prescribed magnetic field for performing writing. As shown in FIG. 19, a part (left side) of the magnetic field application electrodes (CL1, CL2, . . . ) form a semicircular arc-shaped wiring in an in-plan view. Upon applying the write current I_{W} to a spot on a heavy-metal wiring line where a target magnetoresistive effect element for writing is located, the magnetoresistive effect element enters a state where the thermal stability constant is so small that the value cannot be defined as “1” or “0.” In this state, by applying a current in a prescribed direction of the magnetic field application electrodes (CL1, CL2, . . . ), for example, a magnetic field in a prescribed direction is generated according to the current, and writing is performed.

FIG. 20 is a plan view of another AI system according to the sixth embodiment of the present invention different from that in FIG. 19. In FIG. 20, semicircular arc-shaped wiring parts in the magnetic field application electrodes CL1 and CL2 are alternately arranged on the other side of their wire-extending directions. By applying a current in a prescribed direction in both the magnetic field application electrode CL1 and the magnetic field application electrode CL2, a magnetic field in a prescribed direction is generated according to the current, and writing is performed.

Note that FIGS. 19 and 20 focus to clarify the arrangement of the magnetic field application electrodes (CL1, CL2A, etc.) in relation to the positions of the common substrates (SA1 to SAn) and the cross-point memories (CM11, CM21, . . . CM1n, CM2n); accordingly, these figures do not show other members such as the second wiring lines.

### Verification Experiment

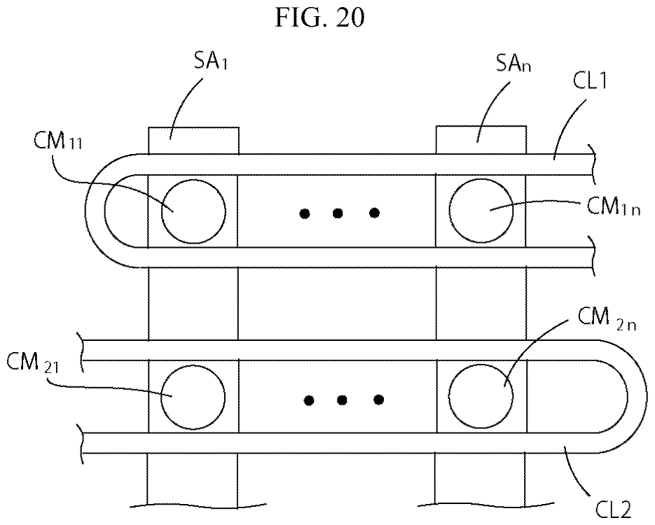

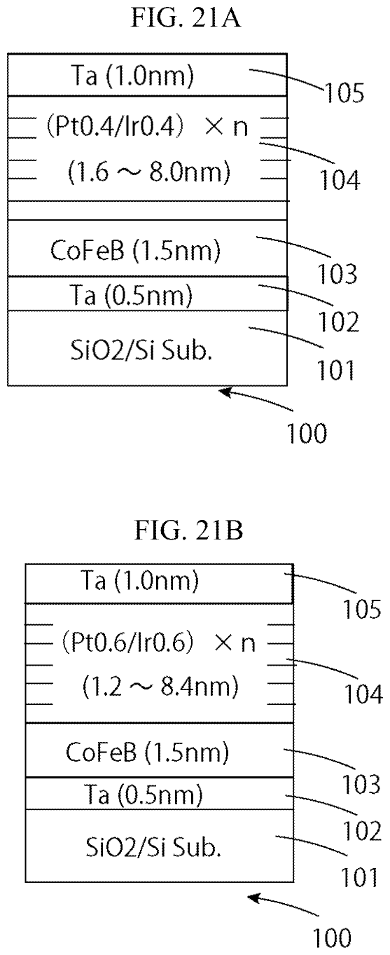

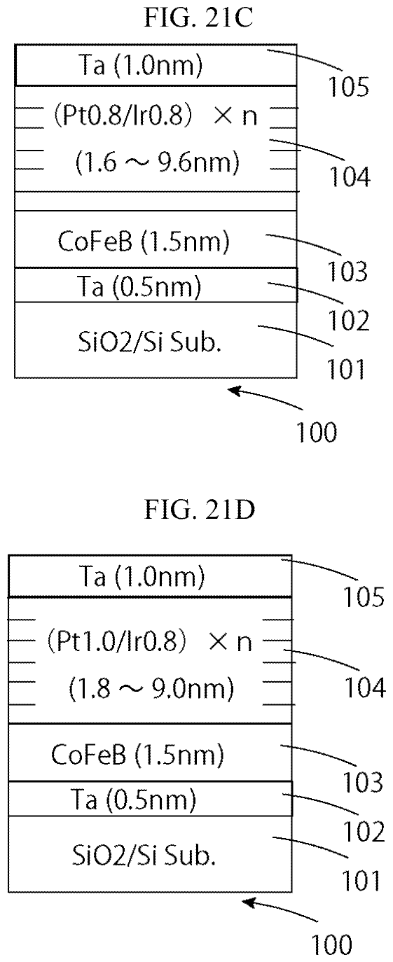

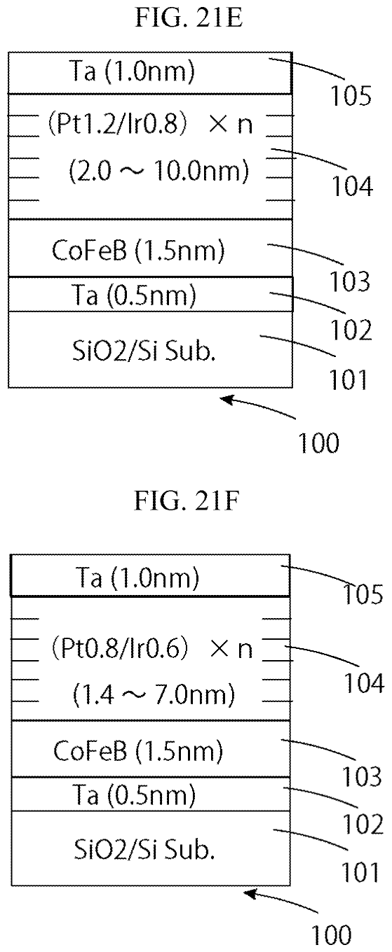

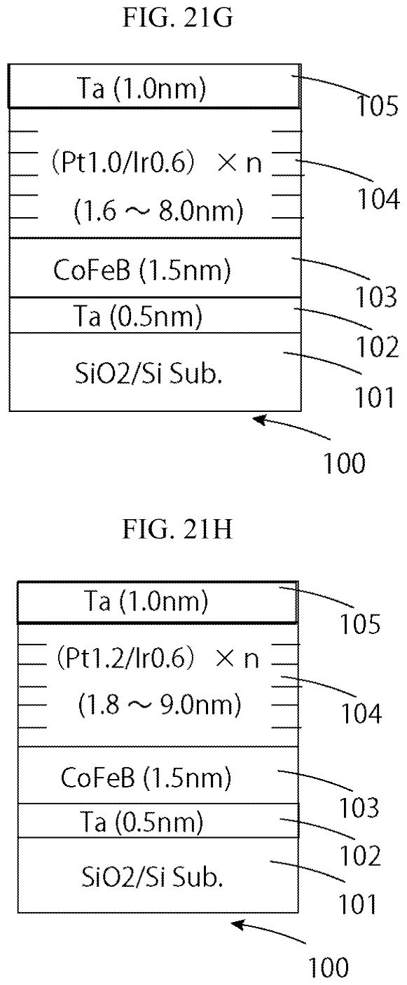

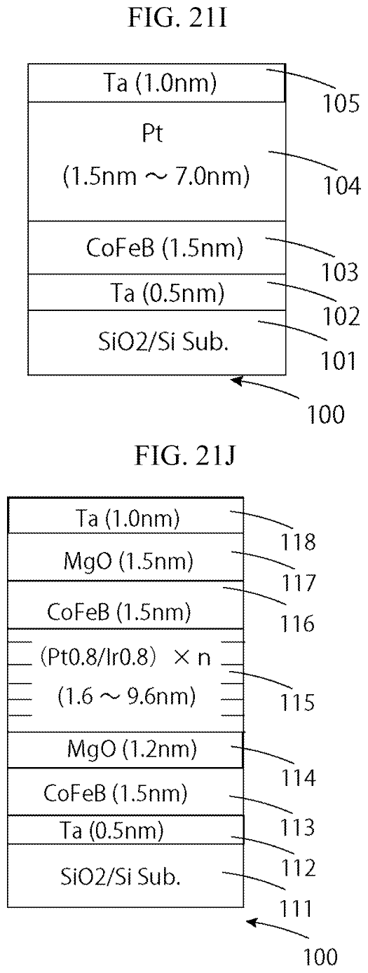

Next, the verification experiment results to verify the magnetic stacked film used for the magnetoresistive effect element according to any embodiment of the present invention will be described. The following samples were fabricated. FIG. 21A through 21H are sectional views of the fabricated samples. Sample 100 includes: an Si substrate 101 with a thermal oxide film; a Ta layer 102 with a thickness of 0.5 nm provided on the thermal oxide film; a CoFeB layer 103 with a thickness of 1.5 nm provided on the Ta layer 102; a heavy-metal layer 104 repeatedly stacked of a Pt layer and an Ir layer; and a Ta layer 105 with a thickness of 1.0 nm provided on the uppermost surface of the heavy-metal layer 104.

In the first sample shown in FIG. 21A, the heavy-metal layer 104 was formed by stacking Pt layers with a thickness of 0.4 nm and Ir layers with a thickness of 0.4 nm; and each stack was fabricated to have 2 to 10 Pt/Ir layers so that the whole thickness of the heavy-metal layer 104 was from 1.6 nm to 8.0 nm.

In the second sample shown in FIG. 21B, the heavy-metal layer 104 was formed by stacking a Pt layer(s) with a thickness of 0.6 nm and an Ir layer(s) with a thickness of 0.6 nm; and each stack was fabricated to have 1 to 7 Pt/Ir layers so that the whole thickness of the heavy-metal layer 104 was from 1.2 nm to 8.4 nm.

In the third sample shown in FIG. 21C, the heavy-metal layer 104 was formed by stacking a Pt layer(s) with a thickness of 0.8 nm and an Ir layer(s) with a thickness of 0.8 nm; and each stack was fabricated to have 1 to 6 Pt/Ir layers so that the whole thickness of the heavy-metal layer 104 was from 1.6 nm to 9.6 nm.

In the fourth sample shown in FIG. 21D, the heavy-metal layer 104 was formed by stacking a Pt layer(s) with a thickness of 1.0 nm and an Ir layer(s) with a thickness of 0.8 nm; and each stack was fabricated to have 1 to 5 Pt/Ir layers so that the whole thickness of the heavy-metal layer 104 was from 1.8 nm to 9.0 nm.

In the fifth sample shown in FIG. 21E, the heavy-metal layer 104 was formed by stacking a Pt layer(s) with a thickness of 1.2 nm and an Ir layer(s) with a thickness of 0.8 nm; and each stack is fabricated to have 1 to 5 Pt/Ir layers so that the whole thickness of the heavy-metal layer 104 was from 2.0 nm to 10.0 nm.

In the sixth sample shown in FIG. 21F, the heavy-metal layer 104 was formed by stacking a Pt layer(s) with a thickness of 0.8 nm and an Ir layer(s) with a thickness of 0.6 nm; and each stack was fabricated to have 1 to 5 Pt/Ir layers so that the whole thickness of the heavy-metal layer 104 was from 1.4 nm to 7.0 nm.

In the seventh sample shown in FIG. 21G, the heavy-metal layer 104 was formed by stacking a Pt layer(s) with a thickness of 1.0 nm and an Ir layer(s) with a thickness of 0.6 nm; and each stack was fabricated to have 1 to 5 Pt/Ir layers so that the whole thickness of the heavy-metal layer 104 was from 1.6 nm to 8.0 nm.

In the eighth sample shown in FIG. 21H, the heavy-metal layer 104 was formed by stacking a Pt layer(s) with a thickness of 1.2 nm and an Ir layer(s) with a thickness of 0.6 nm; and each stack was fabricated to have 1 to 5 Pt/Ir layers so that the whole thickness of the heavy-metal layer 104 was from 1.8 nm to 9.0 nm.

In the comparison stack shown in FIG. 21I, the heavy-metal layer 104 was formed of only a Pt layer; and each stack was fabricated using a Pt layer with a thickness from 1.5 nm to 7.0 nm.

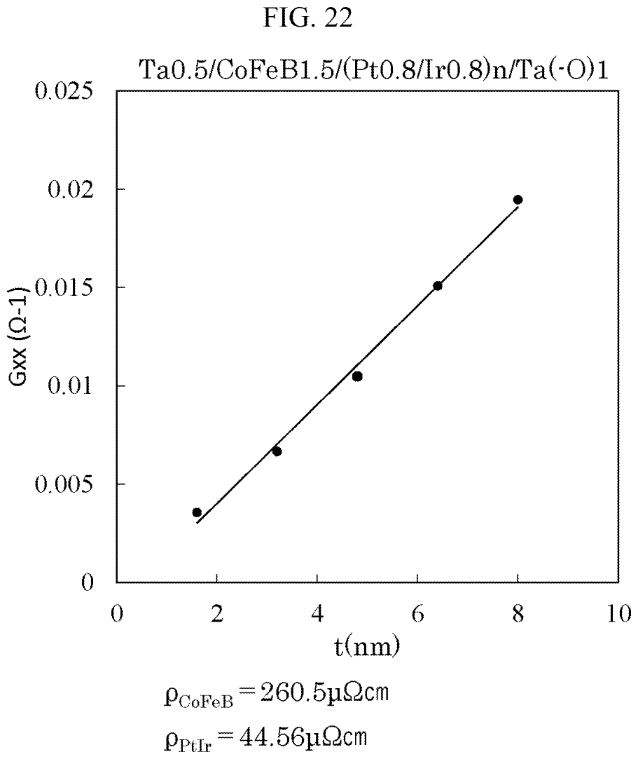

The resistivity, the spin Hall angle (spin orbit torque efficiency), and the spin Hall conductivity in each fabricated sample were estimated using the SMR method. The sheet conductance Gₓₓ (Ω⁻¹) was calculated to find the value of the heavy-metal layer thickness t (nm) dependence. FIG. 22 is a diagram illustrating the heavy-metal layer thickness dependence of sheet conductance of the third sample. The stack in the third sample was Ta 0.5 nm/CoFeB 1.5 nm/(Pt 0.8 nm/Ir 0.8 nm), ₙ/Ta (−o) 1 nm, where n=1 to 5. The resistivity of the heavy-metal layer ρ_{Ptlr} was 44.56 μΩ cm while the resistivity of CoFeB ρ_{CoFeB} was 260.5 μΩ cm.

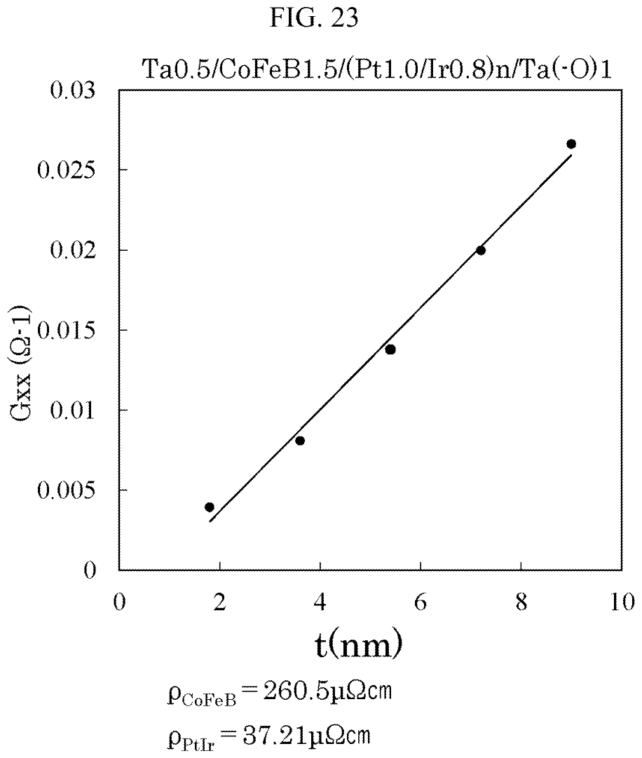

FIG. 23 is a diagram illustrating the heavy-metal layer thickness dependence of sheet conductance of the fourth sample. The stack in the fourth sample was Ta 0.5 nm/CoFeB 1.5 nm/(Pt 1.0 nm/Ir 0.8 nm)ₙ/Ta (−o) 1 nm, where n=1 to 5. The resistivity of the heavy-metal layer ρ_{Ptlr} was 37.21 ρΩ cm while the resistivity of CoFeB ρ_{CoFeB} was 260.5 ρΩ cm.

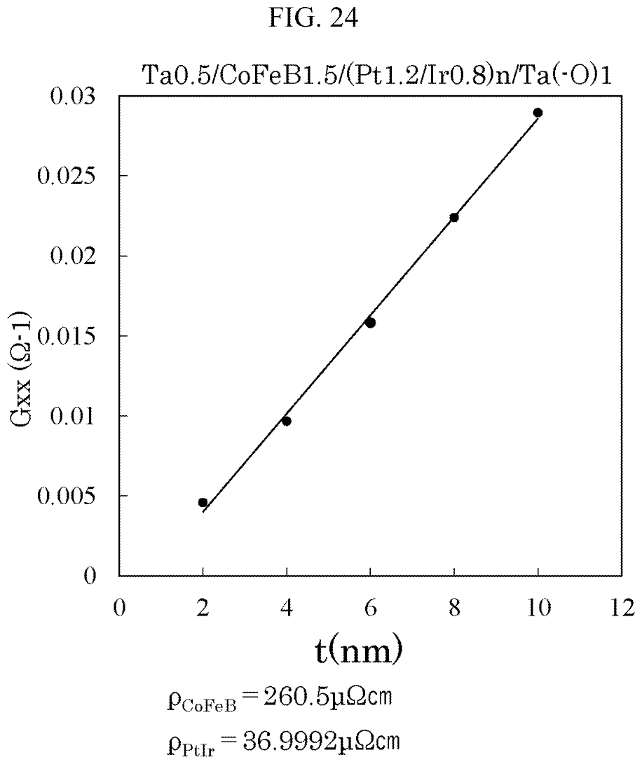

FIG. 24 is a diagram illustrating the heavy-metal layer thickness dependence of sheet conductance of the fifth sample. The stack in the fifth sample was Ta 0.5 nm/CoFeB 1.5 nm/(Pt 1.2 nm/Ir 0.8 nm)ₙ/Ta (−o) 1 nm, where n=1 to 5. The resistivity of the heavy-metal layer ρ_{Ptlr} was 36.9992 μΩ cm while the resistivity of CoFeB ρ_{CoFeB} was 260.5 ρΩ cm.

It was clearly found that the sheet conductance has a linearity with respect to the thickness of the heavy-metal layer 104t from FIGS. 22 through 24. Further, it was found that the resistivity ρ_{Ptlr} of the heavy-metal layer becomes smaller as the thickness ratio (t_Pt/t_Ir) of the Pt layer to the thickness of the Ir layer constituting the laminated film becomes larger.

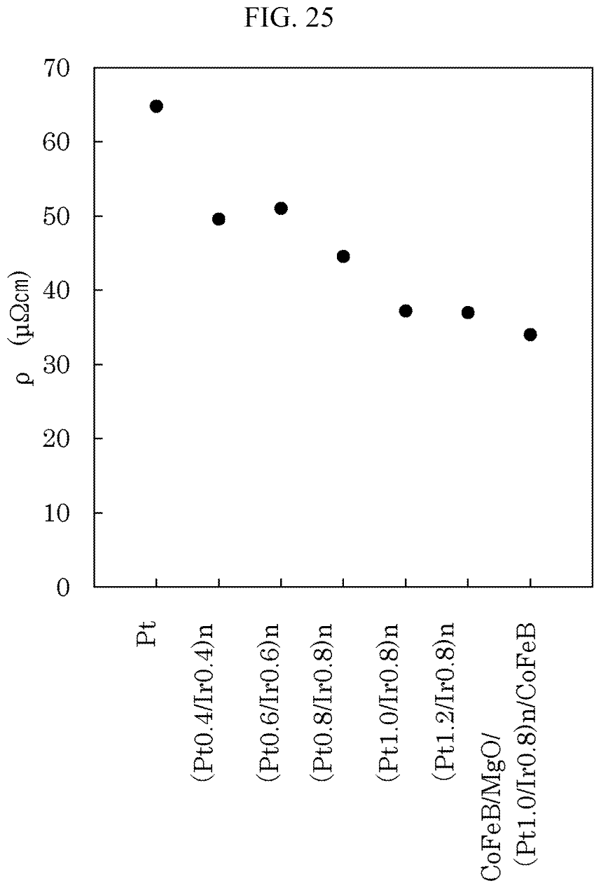

FIG. 25 is the resistivity results calculated from the heavy-metal layer 104 thickness dependence of sheet conductance for the first to the fifth samples. It also illustrates the results for the comparison sample and for the ninth sample, which will be described later. FIG. 25 indicates that the resistivity ρ of the stack of Pt layers and Ir layers was lower than that of the single Pt layer, thus the stack of Pt layers and Ir layers is preferable as a heavy-metal layer than the single Pt layer. In particular, it was found that the resistivity greatly decreased when the thickness ratio of Pt layer/Ir layer was larger than 1.

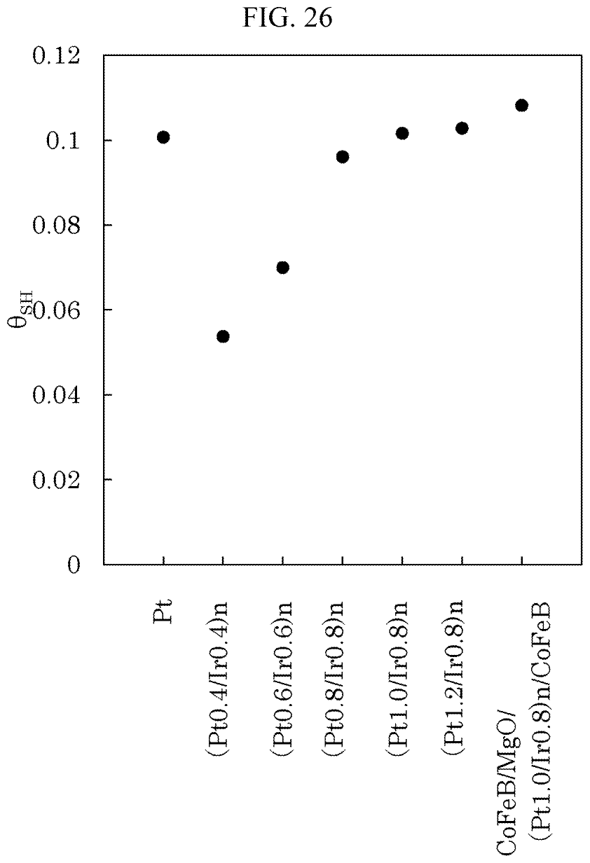

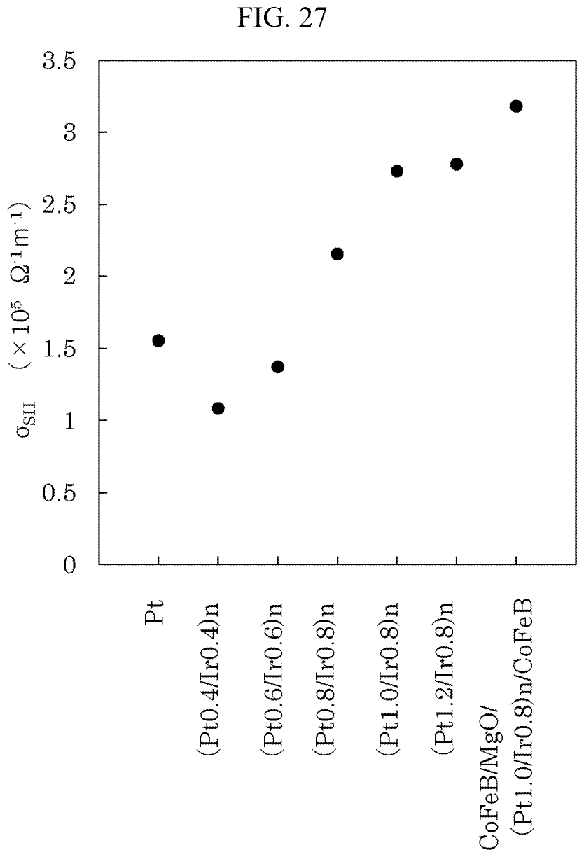

The spin orbit torque efficiency θ_{SH} and the spin Hall conductivity σ_{SH} of the magnetic stacked film for the first to fifth samples were calculated and the results are shown in FIGS. 26 and 27. FIGS. 26 and 27 illustrate the results of the comparison sample and the ninth sample as well. The transverse axis of FIG. 26 indicates each film thickness ratio of the Pt layer and the Ir layer of each sample in the stack conditions while the longitudinal axis indicates the spin orbit torque efficiency θ_{SH}. When the thickness of the Pt layer and the Ir layer is 0.4/0.4 or 0.6/0.6, the spin orbit torque efficiency θ_{SH} becomes lower than the single Pt layer; however, when the thickness of the Pt layer and the Ir layer is 0.8/0.8, 1.0/0.8, or 1.2/0.8, the value is at the same level as that of single Pt layer.

The transverse axis of FIG. 27 indicates each film thickness ratio of the Pt layer and the Ir layer of each sample in the stack conditions while the longitudinal axis indicates the spin Hall conductivity σ_{SH}. It was found that when the thickness of the Pt layer and that of the Ir layer were 0.4/0.4 or 0.6/0.6, the spin Hall conductivity σ_{SH} became lower than the single Pt layer; however, when the thickness of the Pt layer and that of the Ir layer were 0.8/0.8, 1.0/0.8, or 1.2/0.8, the value was higher than that of the single Pt layer.

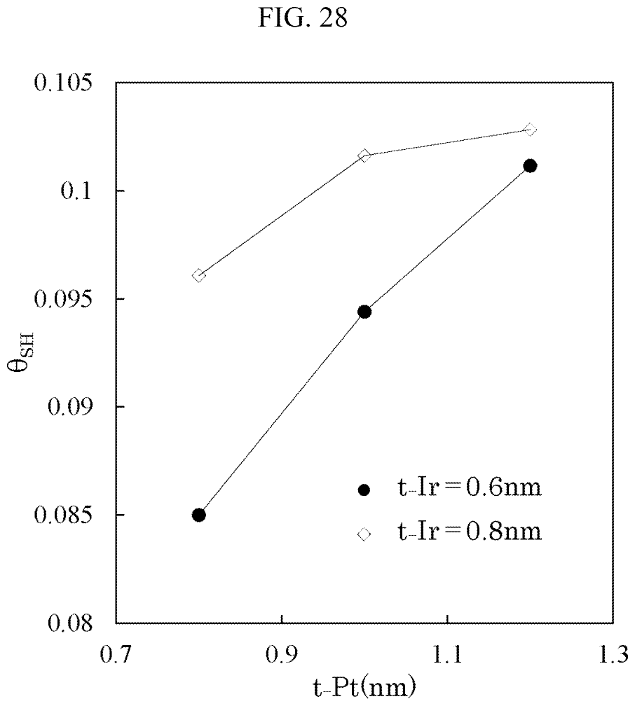

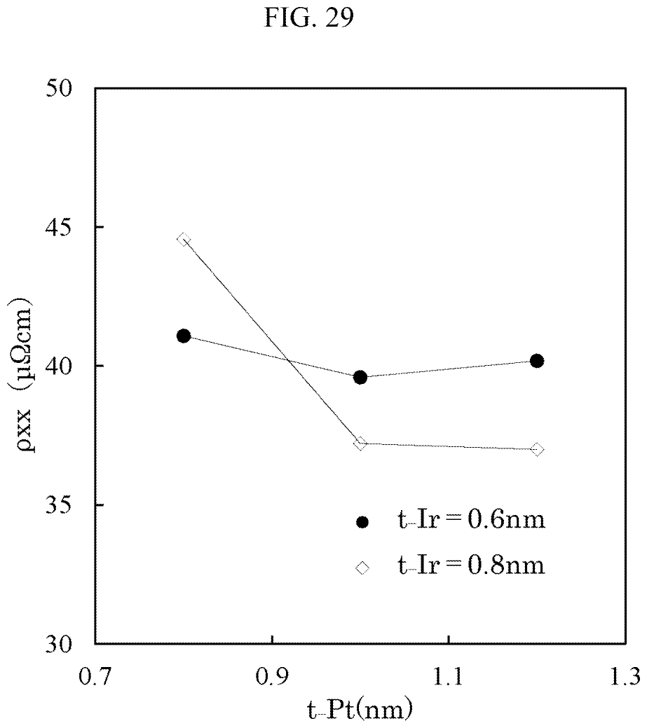

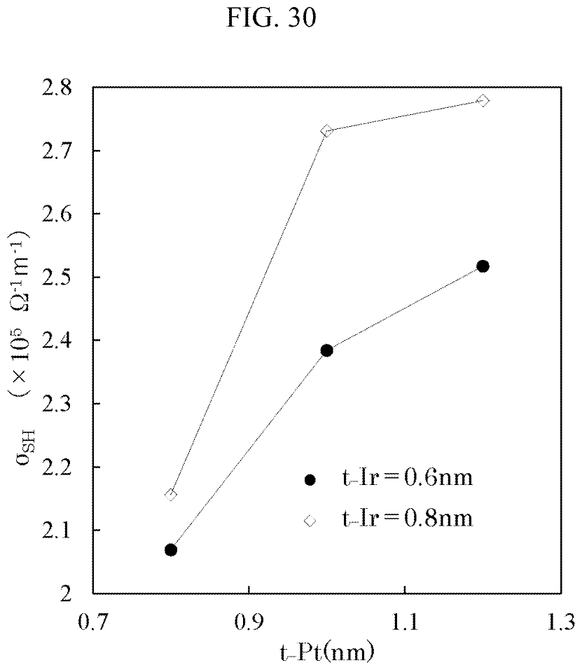

The spin orbit torque efficiency θ_{SH}, the resistivity ρₓₓ, and the spin Hall conductivity σ_{SH} were calculated for the 6th, 7th, and 8th samples in the same manner. The results are shown in FIGS. 28 to 30. FIGS. 28 to 30 illustrate the results of the 3rd to the 5th samples as well. The transverse axis of each figure indicates each film thickness ratio of the Pt layer and the Ir layer of each sample while the longitudinal axis indicates the spin orbit torque efficiency θ_{SH} in FIG. 28, the resistivity ρₓₓ in FIG. 29, and the spin Hall conductivity σ_{SH} in FIG. 30. The value in the case of the Ir layer with a thickness of 0.8 nm is plotted as a black circle (⋅) while the value in the case of the Ir layer with a thickness of 0.6 nm is plotted as a rhombuses (⋄).

FIG. 28 reveals that the spin orbit torque efficiency θ_{SH} increases in accordance with the increase of the thickness of the Pt layer from 0.8 nm, 1.0 nm, 1.2 nm even when the Ir layer has a thickness of either 0.6 nm or 0.8 nm. Compared with the case where a single Pt layer (about 0.1) is used, a sufficient spin orbit torque efficiency θ_{SH} can be obtained when the thickness of the Ir layer t_Ir is 0.6 nm or 0.8 nm and the thickness of the Pt layer t_Pt is in the range of 0.8, 1.0, 1.2 nm. When the Pt layer thickness t_Pt is 0.6 nm in the case of the Ir layer thickness t_Ir 0.6 nm, the spin orbit torque efficiency θ_{SH} is about 0.07, which is not quite preferable.

FIG. 29 reveals that the resistivity ρₓₓ decreases in accordance with the increase of the thickness of the Pt layer from 0.8 nm, 1.0 nm, 1.2 nm even when the Ir layer has a thickness of either 0.6 nm or 0.8 nm. Compared with the case where a single Pt layer (65 ρΩ cm) is used, a low resistivity ρₓₓ can be obtained when the thickness of the Ir layer t_Ir is 0.6 nm or 0.8 nm and the thickness of the Pt layer t_Pt is in the range of 0.8, 1.0, 1.2 nm. When the Ir layer thickness t_Ir is 0.6 nm and the Pt layer thickness t_Pt is 0.6 nm, the resistivity ρₓₓ is about 50 ρΩ cm, which is not quite preferable.

FIG. 30 reveals that the spin Hall conductivity σ_{SH} increases in accordance with the increase of the thickness of the Pt layer from 0.8 nm, 1.0 nm, 1.2 nm even when the Ir layer has a thickness of either 0.6 nm or 0.8 nm. Compared with the case where a single Pt layer (about 1.55×10⁵ Ω⁻¹ m⁻¹) is used, a high spin Hall conductivity σ_{SH} can be obtained when the thickness of the Ir layer t_Ir is 0.6 nm or 0.8 nm and the thickness of the Pt layer t_Pt is in the range of 0.8, 1.0, 1.2 nm. When the Pt layer thickness t_Pt is 0.6 nm in the case of the Ir layer thickness t_Ir 0.6 nm, the spin Hall conductivity σ_{SH} is about 1.4×10⁵ Ω⁻¹ m⁻¹, which is not quite preferable.

The results of the verification experiment revealed the following:
1) The repeated stack of the Ir layer and the Pt layer is preferable as the heavy-metal layer than the single Pt layer because of lower resistivity. Although Pt has a low resistance, it is easy to generate a grain growth and a thin-film has a high resistance, and thus, it is stacked configuration can reduce the resistivity without reducing the inversion efficiency.
2) Each Ir layer included in the heavy-metal layer preferably has a thickness of 0.6 nm or more.
3) Each Pt layer included in the heavy-metal layer preferably has a thickness exceeding 0.6 nm. Because if each layer is thin, for example, every Pt layer/Ir layer has a thickness of 0.4 nm, the spin Hall conductivity σ_{SH} deteriorates compared with that of a single Pt layer (see FIG. 27).
4) The thickness ratio of the Pt layer and the Ir layer in the heavy-metal layer is preferably in the range of 1:0.5 to 1:0.8.
5) The heavy-metal layer as a whole preferably has a thickness of 10 nm or less. A thickness of the heavy-metal layer may be sufficient if it is three or four times as thick as the spin diffusion length; further, it may be thin if only some current can flow through the layer. Because the over-thickness has no impact on the recording layer.
6) Both a Pt layer and an Ir layer are included in the heavy-metal layer, for example, the configuration may be Pt layer/Ir layer/Pt layer or Ir layer/Pt layer/Ir layer.

FIG. 21J is a sectional view of the 9th fabricated sample. The 9th sample 100 included: an Si substrate 111 with a thermal oxide film; a Ta layer 112 with a thickness of 0.5 nm provided on the thermal oxide film; a CoFeB layer 113 with a thickness of 1.5 nm provided on the Ta layer 112; an MgO layer 114 with a thickness of 1.2 nm provided on the CoFeB layer 113; a heavy-metal layer 115 repeatedly stacked of a Pt layer with a thickness of 1.0 nm and an Ir layer with a thickness of 0.8 nm; a CoFeB layer 116 with a thickness of 1.5 nm provided on the heavy-metal layer115; an MgO layer 117 with a thickness of 1.5 nm provided on the CoFeB layer 116; and a Ta layer 118 with a thickness of 1.0 nm provided on the MgO layer 117. The heavy-metal layer 115 was formed by stacking a Pt layer with a thickness of 1.0 nm and an Ir layer with a thickness of 0.8 nm; and each film was fabricated to have 1 to 6 Pt/Ir layers so that the whole thickness of the heavy-metal layer was from 1.6 nm to 9.6 nm.

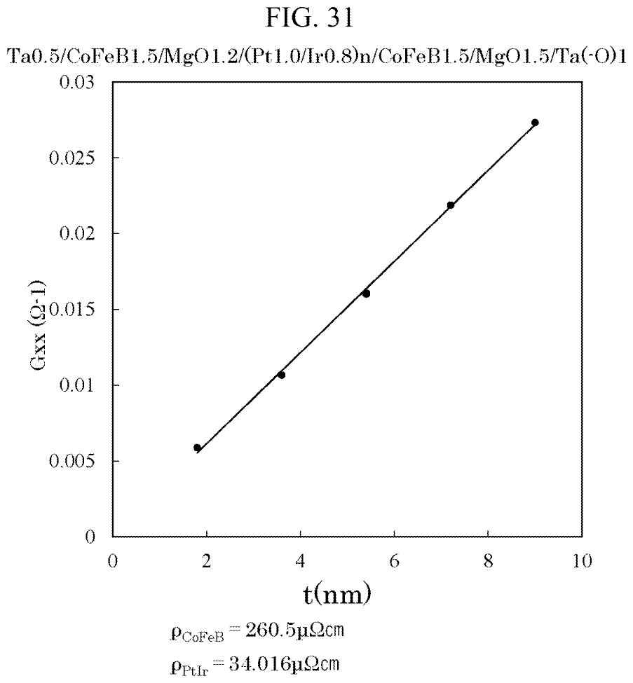

FIG. 31 is a diagram illustrating the heavy-metal layer thickness dependence of sheet conductance of the 9th sample. The stack in the 9th sample was Ta 0.5 nm/CoFeB 1.5 nm/MgO 1.2 nm/(Pt 1.0 nm/Ir 0.8 nm)ₙ/CoFeB 1.5 nm/MgO 1.5 nm/Ta (−o) 1 nm. The resistivity of the heavy-metal layer ρ_{Ptlr} was 34.016 μΩ cm while the resistivity of CoFeB ρ_{CoFeB} was 260.5 ρΩ cm.

The spin orbit torque efficiency θ_{SH} and the spin conductivity σ_{SH} of the 9th sample are also calculated. In the 9th sample, the spin orbit torque efficiency θ_{SH} was about 0.1; the resistivity ρ_{Ptlr} was 35 μΩ cm; and the spin Hall conductivity σ_{SH} was 3.2×10⁵ Ω⁻¹ m⁻¹. It was found that the value was far preferable as a magnetic stacked film (a heavy-metal layer) compared with the 4th sample.

Compared with the results of other samples shown in FIG. 25, the resistivity p calculated in the 9th sample was found to be preferable as the resistivity decreases to 35 ρΩ cm owing to the magnetic layers CoFeB provided on and below the stack of the Pt layer and the Ir layer.

Compared with the results of the 1st to 5th samples shown in FIG. 26, the spin Hall angle θ_{SH} calculated in the 9th sample was found to be preferable as the spin Hall angle θ_{SH} increases to 0.108 owing to the magnetic layers CoFeB provided on and below the stack of the Pt layer and the Ir layer. Note that a spin Hall angle of a single Ir layer is very small, reportedly, 0.01 (PHYSICAL REVIEW B99, 134421, 2019).

Compared with the results of the 1st to 5th samples shown in FIG. 27, the spin Hall conductivity σ_{SH} calculated in the 9th sample was found to be preferable as the spin Hall conductivity σ_{SH} increases to 3.2×10⁵ Ω⁻¹ m⁻¹ owing to the magnetic layers CoFeB provided on and below the stack of the Pt layer and the Ir layer.

FIG. 25 to 27 show the pin generation efficiency θ_{SH}, the resistivity ρPtir, and the spin Hall conductivity σ_{SH} of the 9th sample become preferable; accordingly, it was found that providing the magnetic layers CoFeB on and below the stack of the Pt layer and the Ir layer was preferable. Furthermore, the MgO layer could conceivably provide the Pt layer or the Ir layer adjacent to the MgO layer with crystallinity.

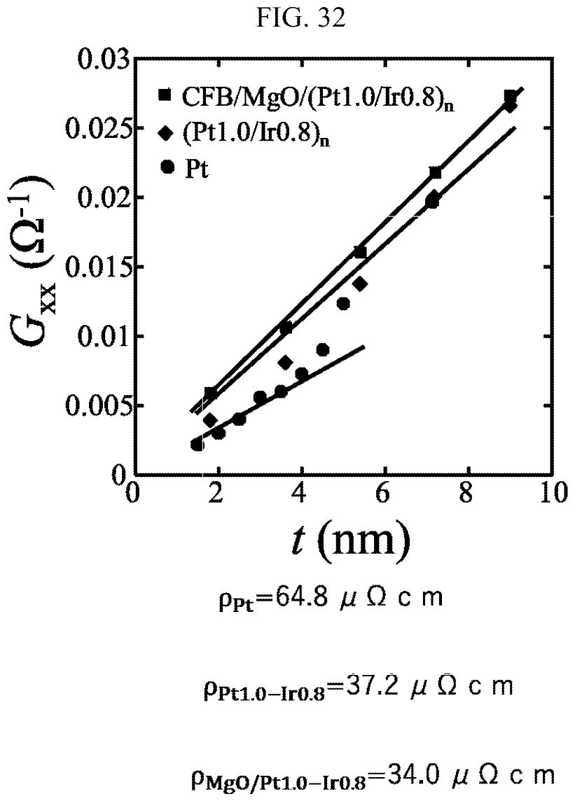

FIG. 32 is a diagram illustrating the heavy-metal layer thickness dependence of sheet conductance. The transverse axis indicates the thickness of the heavy-metal layer while the longitudinal axis indicates the sheet conductance Gₓₓ (Ω⁻¹). The following plots: squares (▪), rhombuses (⋄), and circle (⋅) respectively represents the values of sample: CoFeB/MgO/(Pt1.0/Ir0.8)ₙ, (Pt1.0/Ir0.8)ₙ, and Pt. It can be revealed that each resistivity of Pt, (Pt1.0/Ir0.8)ₙ, and MgO/(Pt1.0/Ir0.8)ₙ decreases to 64.8 μΩ cm, 37.2 μΩ cm, and 34.0 μΩ cm in this order.

As described above, it was found that magnetic layers provided on and below the heavy-metal layer improved characteristics of the spin Hall angle θ_{SH} and the spin Hall conductivity σ_{SH}. Based on this finding, a magnetoresistive effect element according to the second or third embodiment of the present invention, described with reference to FIGS. 9 and 11, will be presumed. The following description is especially referred to FIG. 9. The heavy-metal layer 11 is configured to provide one Co ferromagnetic layer 14 and the other Co ferromagnetic layer 15 on and below the Pt layer 13/Ir layer 12. Generally speaking, Co/Ir/Co is known to generate a strong antiferromagnetic coupling between Co-Co via Ir. However, Ir having a very small spin orbit rorque efficiency θ_{SH} cannot be used as a heavy-metal. As described above, the inventors have revealed that the Pt layer 13/Ir layer 12 can generate a large spin orbit rorque efficiency θ_{SH} and spin Hall conductivity σ_{SH}.

In the 10th sample the stacks were fabricated, which included: a Co layer provided on a Pt/Ta underlayer; an Ir layer and a Pt layer provided on the Co layer in this order; and another Co layer provided on the Pt layer, a Pt layer as a cap layer provided on another Co layer, to examine the magnetic coupling between the layers of Ir/Pt spacer. Note that films were fabricated so that the Pt layer had a thickness between 0.6 nm to 1.0 nm.

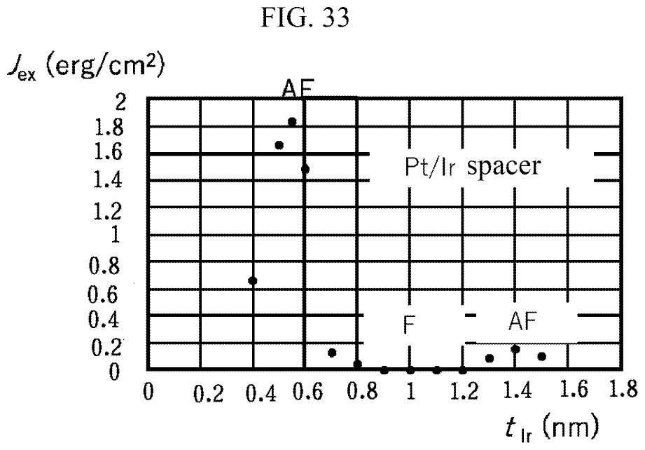

FIG. 33 illustrates the investigation results of magnetic coupling between the layers of Ir/Pt spacer of the tenth sample. The transverse axis indicates the thickness of the Ir layer tₗᵣ while the longitudinal axis indicates the magnitude of interlayer exchange coupling Jₑₓ. According to the results in FIG. 33, strong anti-ferromagnetical coupling even via the Ir/Pt spacer was confirmed. As for the characteristics of the spin orbit torque efficiency θ_{SH} and the spin Hall conductivity σ_{SH} for each of the Ir/Pt layer in the 4th or 5th sample, FIGS. 26 and 27 show good results in (Pt 1.0/Ir 0.8)ₙ, and (Pt 1.2/Ir 0.8)ₙ, where n is between 1 and 5 inclusive. Further, it was found that, as a ferromagnetic layer Co is provided both on and below the Ir/Pt, using this Co/Ir/Pt/Co electrode to change a direction of a write current leads to the following, as shown in FIG. 10: generating an antiferromagnetic coupling between the Co layers; reversing magnetization directions of the Co layers simultaneously without leakage of a stray magnetic field; accordingly, developing a magnetic reversal of the recording layer of the MTJ; and enabling a fabrication of a good SOT device.

Here, the film thickness of Ir is preferably 0.45 to 0.65 nm or 1.3 to 1.5 nm to have an anti-ferromagnetic (AF) coupling, according to FIG. 33. Pt layer is preferably 0.6 to 1.0 nm; Co is preferably equal to or less than 1 nm.

A Pt layer and an Ir layer were compared to find out which was more suitable for an interface with a recording layer of a heavy-metal layer. Table 1 illustrates the spin orbit torque efficiency θ_{SH}, the resistivity ρ (4 cm), and the spin Hall conductivity σ_{SH} in both cases: a Pt layer or an Ir layer is used for an interface with a recording layer of a heavy-metal layer. According to Table 1, a Pt layer was found to be preferable to be used for an interface with a recording layer of a heavy-metal layer than an Ir layer. Thus, it can be concluded that a Pt layer is preferable to be used for the interface with a recording layer of the heavy-metal layer 11 in each of the above-mentioned embodiments.

TABLE 1

| | | ρ | σ_{SH} |
|---|---|---|---|
| | θ_{SH} | (μΩcm) | (10⁵ Ω⁻¹m⁻¹) |
| (Pt0.8/Ir0.8) n (Pt interface) | 0.096 | 44.56 | 2.156 |
| (Pt0.8/Ir0.8) n (Ir interface) | 0.0576 | 43.76 | 1.317 |

How much power consumption could be reduced by using the heavy-metal layer configuration was estimated. Table 2 illustrates relative values of power consumption in the heavy-metal layer configuration. According to Table 2, it was found that a reduction of the power consumption relatively became larger as the ratio of each Pt layer and Ir layer increased from 0.4 nm/0.4 nm, 0.6 nm/0.6 nm, 0.8 nm/0.8 nm, 1.0 nm/0.8 nm, and to 1.2 nm/0.8 nm. Further, it was found that an MgO layer sandwiched between magnetic layers CoFeB led to a relative reduction of the power consumption from 0.33 to 0.26.

TABLE 2

| | Power Consumption |
|---|---|
| Configuration of Heavy-Metal | (Relative value) |
| Pt | 1.00 |
| (Pt0.4/Ir0.4) n | 1.10 |
| (Pt0.6/Ir0.6) n | 0.89 |
| (Pt0.8/Ir0.8) n | 0.50 |
| (Pt1.0/Ir0.8) n | 0.33 |
| (Pt1.2/Ir0.8) n | 0.32 |
| CoFeB/MgO1.2/(Pt1.0/Ir0.8) n/CoFeB | 0.26 |

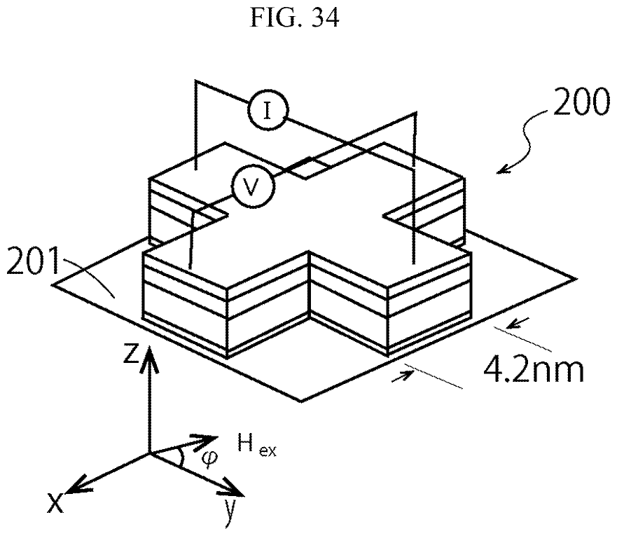

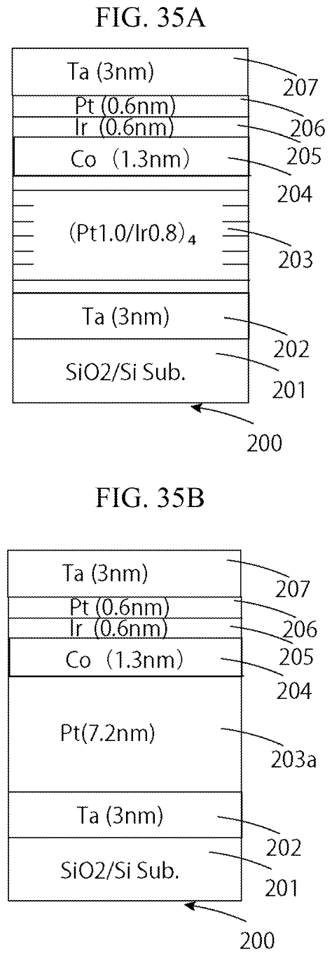

FIG. 34 is a diagram schematically illustrating a Hall bar and a measurement system that have been fabricated as the 11th sample. FIG. 35A is a sectional view of the eleventh fabricated sample. As shown in FIG. 35A, the 11th sample included: an Si substrate 201 with a thermal oxide film; a Ta layer 202 with a thickness of 3 nm provided on the thermal oxide film; a heavy-metal layer 203 formed by alternately stacking a Pt layer with a thickness of 1.0 nm and an Ir layer with a thickness of 0.8 nm four times and provided on the Ta layer 202; a Co layer 204 with a thickness of 1.3 nm provided on the heavy-metal layer 203; an Ir layer 205 with a thickness of 0.6 nm provided on the Co layer 204; a Pt layer 206 with a thickness of 0.6 nm provided on the Ir layer 205; and a Ta layer 207 with a thickness of 3 nm provided on the Pt layer 206.

FIG. 35B is a sectional view of another fabricated sample for comparison. As shown in FIG. 35B, the comparison sample included: an Si substrate 201 with a thermal oxide film; a Ta layer 202 with a thickness of 3 nm provided on the thermal oxide film; a Pt layer 203a with a thickness of 7.2 nm provided on the Ta layer 202; a Co layer 204 with a thickness of 1.3 nm provided on the Pt 203a; an Ir layer 205 with a thickness of 0.6 nm provided on the Co layer 204: a Pt layer 206 with a thickness of 0.6 nm provided on the Ir layer 205; and a Ta layer 207 with a thickness of 3 nm provided on the Pt layer 206.

These samples were etched into a Hall bar, as shown in FIG. 34, by photolithography and Ar Ion Milling. A pulse current I was supplied in y direction to measure a Hall voltage V, and a pulse current I dependence of Hall resistivity R_{xy} (Ω), where R_{xy} (Ω)=V/I.

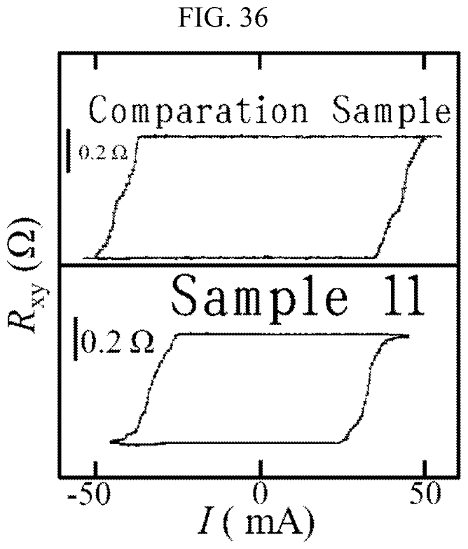

FIG. 36 is a diagram illustrating the pulse current dependence of Hall resistivity R_{xy} (Ω) of the 1st sample and another comparison sample. Here, the transversal axis indicates the pulse current I (mA) and the longitudinal axis indicates the Hall resistivity R_{xy} (Ω). The results were observed when applying a pulse current I for 200 μseconds and a constant external magnetic field Hₑₓ of −26 mT in direction of the pulse current I (φ=0 degree). What observed was an increase of the Hall resistivity R_{xy} at a certain value when applying a pulse current in +direction and a decrease of the Hall resistivity R_{xy} at a certain value when applying a pulse current in—direction; and thus, a magnetic moment of the Co layer 204 was magnetically reversed by the pulse current.

The absolute value of an inversion current in these samples was found that when a multilayered electrode of a Pt layer(s) and an Ir layer(s) was used for the heavy-metal layer 203, the inversion current was decreased to about 70 percent comparing with that when an electrode of Pt layer 203a was used.

Observing the resistivity ρₓₓ of the Pt with a thickness of 7.2 nm and the resistivity of the four-layer stack of Pt of 1.0 nm and Ir 0.8 nm, (Pt 1.0 nm/Ir 0.8 nm)₄, both values are ρₓₓ=37.2 ρΩ cm, and thus, the decrease of the inversion current could conceivably be due to an increase of the spin conversion efficiency θ_{SH} in the multilayered Pt/Ir than that in the Pt layer.

Pt layer and Ir layer forming the heavy-metal layer may have either a constant or variable thickness. Each MTJ may have either a vertical or in-plane magnetization.

Note that a magnetoresistive effect element according to the embodiments of the present invention is fabricated by depositing each element in order using a sputtering and so on; applying a magnetic field in a direction to control the magnetization direction; and performing a thermal treatment.

### REFERENCE SIGNS LIST

1: substrate
2: buffer layer
10, 30, 50: magnetoresistive effect element
11: heavy-metal layer
12: Ir layer
13: Pt layer
14: one ferromagnetic layer
15: the other ferromagnetic layer
16: recording layer
17: tunnel barrier layer
18: reference layer
19: cap layer
60: magnetic memory

1. A magnetoresistive effect element, comprising:
a heavy-metal layer formed by stacking an Ir layer and a Pt layer;
a recording layer provided to be opposed to the heavy-metal layer and formed to include a first ferromagnetic layer having a reversible magnetization;
a reference layer formed to include a second ferromagnetic layer in which a magnetization direction is fixed; and
a barrier layer sandwiched between the first ferromagnetic layer and the second ferromagnetic layer, and formed of an insulator;
wherein the magnetoresistive effect element is configured such that a magnetization direction in the first ferromagnetic layer is reversed with a flow of a write current in the heavy-metal layer.

2. The magnetoresistive effect element according to claim 1,
wherein the heavy-metal layer is formed by repeatedly stacking the Ir layer and the Pt layer.

3. The magnetoresistive effect element according to claim 1,
wherein the Pt layer provided outermost on the heavy-metal layer forms an interface with the recording layer.

4. The magnetoresistive effect element according to claim 1,
wherein the Pt layer has a thickness equal to or greater than 0.6 nm and equal to or less than 1.5 nm.

5. The magnetoresistive effect element according to claim 1,
wherein the Ir layer has a thickness equal to or greater than 0.6 nm and equal to or less than 1.5 nm.

6. The magnetoresistive effect element according to claim 1,
wherein the Pt layer and the Ir layer in the heavy-metal layer have a thickness ratio in a range of 1:0.5 to 1:0.8.

7. The magnetoresistive effect element according to claim 1,
wherein the heavy-metal layer is formed by stacking the Ir layer and the Pt layer one by one,
the element further comprises a third ferromagnetic layer and a fourth ferromagnetic layer; and
the third ferromagnetic layer and the fourth ferromagnetic layer sandwich the Ir layer and the Pt layer.

8. The magnetoresistive effect element according to claim 1,
wherein shapes of the recording layer, the barrier layer, and the reference layer viewed from a stack direction of the heavy-metal layer are asymmetrical to any line along a direction of a write current in the heavy-metal layer.

9. The magnetoresistive effect element according to claim 1,
wherein shapes of the recording layer, the barrier layer, and the reference layer viewed from a stack direction of the heavy-metal layer are symmetrical to any one of lines along a direction of the write current in the heavy-metal layer.

10. A magnetic memory,
wherein a plurality of the magnetoresistive effect elements, each of which includes the recording layer, the barrier layer, and the reference layer, according to claim 1 is provided on the same heavy-metal layer.

11. An artificial intelligence system,
wherein the magnetoresistive effect element according to claim 1 is used for an electronic neuron to which a weighted sum of a resistive crossbar network is inputted.

12. The artificial intelligence system according to claim 11,
wherein the magnetoresistive memory element is used for a cross-point memory of a resistive crossbar network.

13. The magnetoresistive effect element according to claim 2,
wherein the Pt layer provided outermost on the heavy-metal layer forms an interface with the recording layer.

14. The magnetoresistive effect element according to claim 2,
wherein the Pt layer has a thickness equal to or greater than 0.6 nm and equal to or less than 1.5 nm per layer.

15. The magnetoresistive effect element according to claim 3,
wherein the Pt layer has a thickness equal to or greater than 0.6 nm and equal to or less than 1.5 nm per layer.

16. The magnetoresistive effect element according to claim 2,
wherein the Ir layer has a thickness equal to or greater than 0.6 nm and equal to or less than 1.5 nm.

17. The magnetoresistive effect element according to claim 3,
wherein the Ir layer has a thickness equal to or greater than 0.6 nm and equal to or less than 1.5 nm.

18. The magnetoresistive effect element according to claim 4,
wherein the Ir layer has a thickness equal to or greater than 0.6 nm and equal to or less than 1.5 nm.

19. The magnetoresistive effect element according to claim 2,
wherein the Pt layer and the Ir layer in the heavy-metal layer have a thickness ratio in a range of 1:0.5 to 1:0.8.

20. The magnetoresistive effect element according to claim 3,
wherein the Pt layer and the Ir layer in the heavy-metal layer have a thickness ratio in a range of 1:0.5 to 1:0.8.

21. The magnetoresistive effect element according to claim 4,
wherein the Pt layer and the Ir layer in the heavy-metal layer have a thickness ratio in a range of 1:0.5 to 1:0.8.

22. The magnetoresistive effect element according to claim 5,
wherein the Pt layer and the Ir layer in the heavy-metal layer have a thickness ratio in a range of 1:0.5 to 1:0.8.
